(19) United States
(12) Patent Application Publication
(10) Pub. No.: US 2025/0372527 A1
(43) Pub. Date: Dec. 4, 2025

(54) SEMICONDUCTOR MODULE INCLUDING ACTIVE LOCAL SILICON INTERCONNECT (LSI) DIE AND METHODS OF FORMING THE SAME

(71) Applicant: Taiwan Semiconductor Manufacturing Company Limited, Hsinchu (TW)

(72) Inventors: Wei-Yu Chen, Hsinchu City (TW); Hao-Yi Tsai, Hsinchu City (TW); Tsung-Ding Wang, Tainan (TW); Yao-Cheng Wu, Hsinchu (TW)

(21) Appl. No.: 18/732,668

(22) Filed: Jun. 4, 2024

(51) Int. Cl. H01L 23/538; H01L 23/00; H01L 23/498; H01L 25/00; H01L 25/065; H10B 80/00

(52) U.S. Cl. CPC H01L 23/5386; H01L 23/49827; H01L 23/49838; H01L 25/0655; H01L 25/50; H10B 80/00; H01L 24/08; H01L 24/16; H01L 24/32; H01L 24/73; H01L 2224/08225; H01L 2224/16225; H01L 2224/32225; H01L 2224/73204; H01L 2924/1431; H01L 2924/1436

(57) ABSTRACT

A semiconductor module may include an interposer including an active local silicon interconnect (LSI) die, a first semiconductor die on the interposer, and a plurality of second semiconductor dies adjacent the first semiconductor die on the interposer and coupled to the first semiconductor die by the active LSI die. A method of forming a semiconductor module may include attaching an active local silicon interconnect (LSI) die to a carrier substrate, forming a molding material layer around the active LSI die, forming an upper redistribution layer (RDL) structure on the active LSI die and the molding material layer, attaching a first semiconductor die to the upper RDL structure; and attaching a plurality of second semiconductor dies to the upper RDL structure such that the plurality of second semiconductor dies is coupled to the first semiconductor die by the active LSI die.

### BACKGROUND

High Bandwidth Memory (HBM) is a memory interface that may use three-dimensional stacked synchronous dynamic random access memory (3D-stacked SDRAM). HBM may be used in conjunction with various host dies including high-performance graphics accelerators, network devices, application specific integrated circuits (ASICs), graphics processing units (GPUs) and central processing units (CPUs). HBM may achieve higher bandwidth than double data rate (DDR) SDRAM or graphics double data rate (GDDR) SDRAM while using less power and requiring less space.

HBM may include a stack of DRAM dies on an optional base die which may include buffer circuitry and test logic. The stack of DRAM dies may be connected to a memory controller on a GPU or CPU through a substrate such as an interposer. Within the stack of DRAM dies, the DRAM dies may be vertically interconnected by through-silicon vias (TSVs) and microbumps.

A memory bus for HBM may be very wide compared to other DRAM memories. In particular, an HBM die stack including four DRAM dies (4-Hi HBM stack) may have two 128-bit channels per die for a total of 8 channels and a width of 1024 bits in total. A graphics card/GPU with four 4-Hi HBM stacks would therefore have a memory bus with a width of 4096 bits. In comparison, the bus width of GDDR SDRAM may be 32 bits, with 16 channels for a graphics card with a 512-bit memory interface.

HBM may be tightly coupled to a host die (e.g., GPU, CPU, etc.) with a distributed interface. The interface may be divided into independent channels. The channels may be completely independent of one another and are not necessarily synchronous to each other. HBM may use a wide-interface architecture to achieve high-speed, low-power operation. Each channel interface may maintain a 128-bit data bus operating at double data rate. HBM may support a transfer rate of at least 1 GT/s per pin (transferring 1 bit), yielding an overall package bandwidth of at least 128 GB/s.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A illustrates a vertical cross-sectional view of the semiconductor module according to one or more embodiments.

FIG. 1B illustrates a plan view (e.g., top-down view) of the semiconductor module according to one or more embodiments.

FIG. 2A is a vertical cross-sectional view of an intermediate structure including the active LSI die and the TIV on a first carrier substrate (e.g., carrier wafer) according to one or more embodiments.

FIG. 2B is a vertical cross-sectional view of an intermediate structure including the molding material layer according to one or more embodiments.

FIG. 2C is a vertical cross-sectional view of an intermediate structure including the upper RDL structure on the molding material layer according to one or more embodiments.

FIG. 2D is a vertical cross-sectional view of an intermediate structure including the first semiconductor die and second semiconductor die on the upper RDL structure according to one or more embodiments.

FIG. 2E illustrates a vertical cross-sectional view of an intermediate structure including the plurality of C4 bumps according to one or more embodiments.

FIG. 3 is a flow chart illustrating a method of forming the semiconductor module according to one or more embodiments.

FIG. 4 is a vertical cross-sectional view of a package structure according to one or more embodiments.

FIG. 5A is a vertical cross-sectional view of the semiconductor module having the first alternative configuration according to one or more embodiments.

FIG. 5B is a plan view (e.g., top-down view) of the semiconductor module having the first alternative configuration according to one or more embodiments.

FIG. 5C is a detailed plan view (e.g., top-down view) of a portion of the semiconductor module having the first alternative configuration according to one or more embodiments.

FIG. 6A is a vertical cross-sectional view of the semiconductor module having the second alternative configuration according to one or more embodiments.

FIG. 6B is a plan view (e.g., top-down view) of the semiconductor module having the second alternative configuration according to one or more embodiments.

FIG. 6C is a detailed plan view (e.g., top-down view) of a portion of the semiconductor module having the second alternative configuration according to one or more embodiments.

FIG. 7A is a plan view (e.g., top-down view) of the semiconductor module having the third alternative configuration according to one or more embodiments.

FIG. 7B is a detailed plan view (e.g., top-down view) of a portion of the semiconductor module having the third alternative configuration according to one or more embodiments.

FIG. 8A is a vertical cross-sectional view of a semiconductor module having a fourth alternative configuration according to one or more embodiments.

FIG. 8B illustrates a plan view (e.g., top-down view) of the semiconductor module having the fourth alternative configuration according to one or more embodiments.

FIG. 9 is a vertical cross-sectional view of a package structure including the semiconductor module having the fourth alternative configuration according to one or more embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. Unless explicitly stated otherwise, each element having the same reference numeral is presumed to have the same material composition and to have a thickness within a same thickness range.

Currently, metal layers may be used to transfer data between an HBM die (e.g., HBM4) and a die such as a central processing unit (CPU) die, a graphics processing unit (GPU) die, a system on chip (SoC) die, a system on integrated chips die, etc. However, the communication speed provided by the metal layers may not be adequate for powerful high-powered computing (HPC) in the future. In particular, placing an HBM die aside an SoC die for connection using passive local silicon interconnect (LSI) with metal layers may require more space for both the SoC die and the HBM die. To enhance bandwidth by adding more HBM die, more SoC dies may need to be placed and connected, which may enlarge the top die reticle size.

One or more embodiments of the present disclosure may include an active LSI for bridging between an HBM die and another die such as a central processing unit (CPU) die, graphics processing unit (GPU) die or SoC die. In particular, one or more embodiments may include active LSI for enabling double raw HBM (e.g., double raw placement of HBM) bridging in a chip-on-wafer-on-substrate process.

At least one embodiment may include a new structure and method for enhancing HBM bandwidth and performance (e.g., in a chip-on-wafer-on-substrate process) by embedding an active LSI die in an interposer (e.g., a reconstituted wafer (RW) interposer). The interposer may be constructed, for example, using organic material such as molding material. Advantages of the new structure and method may include, for example, doubling the quantity of HBM to enhance bandwidth, enabling connection of double raw HBM with an SoC die, replacing a 6 mm metal layer or layers with back end of line (BEOL) metal layers (My/Myy) to accelerate communication speed, and forming a memory controller within the active LSI die to extend HBM bridges and relieve an area of the SoC die.

The one or more embodiments disclosed herein may include several novel aspects. In particular, the one or more embodiments may enable additional (additional (extra) active area for memory controller logic, providing relief to extra) active area for memory controller logic, providing relief to an SoC die area limit. The one or more embodiments may free up more space for HBM. The one or more embodiments may also replace a power hungry memory interface (e.g., HBM physical layer (HBM PHY), universal chiplet interconnect express (UCIe) PHY, etc.) with a digital lite input/output (I/O) to achieve greater bandwidth.

HBM PHY may include a type of memory interface that enables high-bandwidth communication between a memory device and a host die (e.g., CPU, GPU, SOC, etc.). HBM PHY may be used in applications that require high memory bandwidth, such as graphics processing, high-performance computing, and networking. HBM PHY may be based on a standard of the Joint Electron Device Engineering Council (JEDEC standard) to define HBM base-die area for a die-to-die (D2D) connection. Digital lite I/O is a type of SoC internet protocol (IP) for I/O.

The one or more embodiments may include an active LSI for double raw HBM bridges. The one or more embodiments may also include an active LSI for four times (4×) HBM bridges.

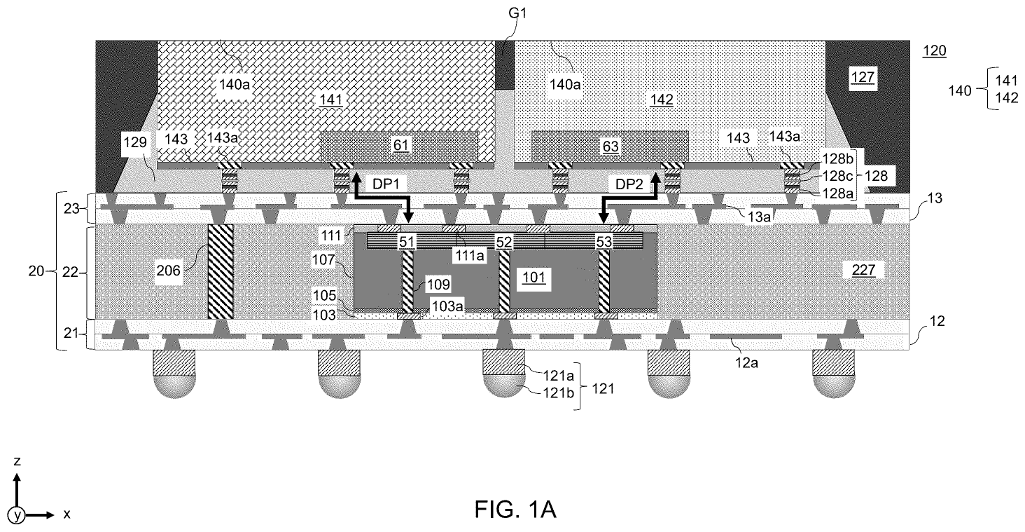

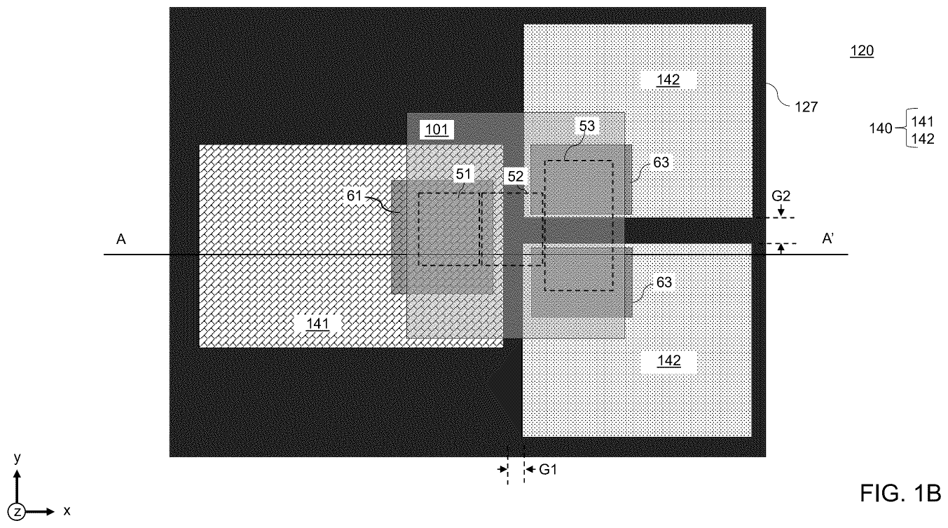

FIGS. 1A-1B provide different views of a semiconductor module 120 according to one or more embodiments. FIG. 1A illustrates a vertical cross-sectional view of the semiconductor module 120 according to one or more embodiments. FIG. 1B illustrates a plan view (e.g., top-down view) of the semiconductor module 120 according to one or more embodiments. The vertical cross-sectional view in FIG. 1A may be along the line A-A′ in FIG. 1B.

As illustrated in FIG. 1A, in at least one embodiment, the semiconductor module 120 may include an interposer 20 and a plurality of semiconductor dies 140 including a first semiconductor die 141 and a plurality of second semiconductor dies 142 (see FIG. 1B) on the interposer 20. The interposer 20 may include an active local silicon interconnect (LSI) die 101 therein. The active LSI die 101 may be referred to, for example, as a bridge die. The semiconductor dies 140 may be located over the active LSI die 101 and may be interconnected by the active LSI die 101.

In at least one embodiment, the first semiconductor die 141 may include a primary die and the second semiconductor dies 142 may include a secondary die. In particular, the first semiconductor die 141 may include a host die such as a CPU die, a GPU die, an SoC die, a system on integrated chips die, etc., and the second semiconductor dies 142 may include an HBM die. Thus, in at least one embodiment, the first semiconductor die 141 may be referred to as the host die 141 and the second semiconductor dies 142 may be referred to as HBM dies 142.

Although the semiconductor module 120 is illustrated as including a particular number of semiconductor dies having a particular arrangement, the number of semiconductor dies and the arrangement of the semiconductor dies is not limited to any particular number and arrangement. In particular, the semiconductor module 120 may include any number and arrangement of semiconductor dies and any number and arrangement of semiconductor die sets.

The interposer 20 is not necessarily limited to any particular materials or configuration. The interposer 20 may include, for example, organic material (e.g., dielectric polymer), inorganic material (e.g., silicon), glass substrate, etc. In at least one embodiment, as illustrated in FIG. 1A, the interposer 20 may include a lower RDL structure 21, an interposer molded portion 22 on the lower RDL structure 21 and an upper RDL structure 23 on the interposer molded portion 22. The lower RDL structure 21 may be located on a side of the interposer molded portion 22 opposite the upper RDL structure 23.

In at least one embodiment, the lower RDL structure 21 may include a plurality of dielectric layers 12 (also referred to as polymer layers 12) and a plurality of redistribution layers 12a stacked alternately. While FIG. 1A illustrates two (2) layers of polymer layers, the number of polymer layers 12 and/or the number of redistribution layers 12a in the lower RDL structure 21 are not limited by the disclosure.

In at least one embodiment, the polymer layers 12 may include, for example, polyimide (PI), epoxy resin, acrylic resin, phenol resin, benzocyclobutene (BCB), polybenzoxazole (PBO), or any other suitable polymer-based dielectric material. In some embodiments, the redistribution layers 12a may include conductive materials. The conductive materials may include metal such as copper, aluminum, nickel, titanium, a combination thereof. Other suitable conductive materials may be within the contemplated scope of disclosure.

The redistribution layers 12a may include metallic connection structures that provide electrical connection to and from nodes in the lower RDL structure 21. The redistribution layers 12a may include a metallic seed layer and a metallic fill material on the metallic seed layer. The metallic seed layer may include, for example, a stack of a titanium barrier layer and a copper seed layer. The titanium barrier layer may have thickness in a range from 50 nm to 500 nm, and the copper seed layer may have a thickness in a range from 50 nm to 500 nm, although lesser or greater thicknesses may also be used. The metallic fill material for the redistribution layers 12a may include copper, nickel, or copper and nickel. Other suitable metallic fill materials are within the contemplated scope of disclosure. The thickness of the metallic fill material that is deposited for each redistribution layers 12a may be in a range from 2 microns to 40 microns, such as from 4 microns to 10 microns, although lesser or greater thicknesses may also be used.

In at least one embodiment, the redistribution layers 12a may include a plurality of traces (lines) and a plurality of vias connecting the plurality traces to each other. The traces may be respectively located on the polymer layers 12, and may extend in the x-direction (first horizontal direction) and y-direction (second horizontal direction) on an upper surface of the polymer layers 12.

As further illustrated in FIG. 1A, a plurality of C4 bumps 121 may connected to a via of the redistribution layers 12a on a board-side surface of the lower RDL structure 21, respectively. In at least one embodiment, the C4 bumps 121 may include underbump metallurgy (UBM) layers (not shown) on the via. The C4 bumps 121 may further include a metal pillar 121a (e.g., copper pillar) on the UBM layers and a solder bump 121b (e.g., SnAg solder bump) on the metal pillar 121a. The C4 bumps 121 may allow the semiconductor module 120 may be connected to a substrate such as a package substrate.

The interposer molded portion 22 may have a length in the x-direction that is substantially the same as a length in the x-direction of the lower RDL structure 21. The interposer molded portion 22 may have a width in the y-direction that is substantially the same as a width in the y-direction of the lower RDL structure 21. The interposer molded portion 22 may have a thickness in the z-direction greater than a thickness of the lower RDL structure 21.

The interposer molded portion 22 may include a molding material layer 227 (e.g., encapsulation layer) formed on the lower RDL structure 21. The molding material layer 227 may include an organic molding material or inorganic molding material. In at least one embodiment, the molding material layer 227 may be formed of a curable material that may cure to form a hard, solid structure. The molding material layer 227 may include, for example, epoxy molding compound (EMC). In at least one embodiment, the molding material layer 227 may include a polymeric material and in particular, an epoxy-based polymeric material. Other suitable molding materials may be used.

In at least one embodiment, the molding material layer 227 may have a coefficient of thermal expansion (CTE) that is substantially similar to a CTE of the lower RDL structure 21. In at least one embodiment, the molding material layer 227 may include an added material (e.g., filler material) for improving a property of the molding material layer 227 (e.g., thermal conductivity, CTE, etc.). The added material may include, for example, metal powder, metal oxide powder, etc. Other materials in the molding material layer 227 are within the contemplated scope of the disclosure.

The interposer molded portion 22 of the interposer 20 may also include the active LSI die 101. The molding material layer 227 may be formed around the active LSI die 101 in the x-direction and y-direction. In at least one embodiment, the active LSI die 101 may be substantially embedded in the molding material layer 227. The active LSI die 101 may be mounted on the lower RDL structure 21.

The active LSI die 101 may include a lower dielectric layer 103 (e.g., passivation layer) and one or more lower contacts 103a in the lower dielectric layer 103. The lower dielectric layer 103 may include, for example, silicon oxide, silicon nitride, low-k dielectric materials such as carbon-doped oxides, extremely low-k dielectric materials such as porous carbon doped silicon dioxide, a combination thereof or other suitable material. Other suitable metal materials are within the contemplated scope of disclosure. The lower contacts 103a may include metals, metal alloys, and/or other metal-containing compounds (e.g., Cu, Al, Mo, Co, Ru, W, TiN, TaN, WN, etc.). Other suitable metal materials are within the contemplated scope of disclosure.

The active LSI die 101 may be bonded to the lower RDL structure 21 such that the lower contacts of the redistribution layers 13a contact metal vias in the redistribution layers 12a of the lower RDL structure 21. The active LSI die 101 may thereby be electrically connected to the lower RDL structure 21.

The active LSI 101 may also include an isolation layer 105 on the lower dielectric layer 103. The isolation layer 105 may include, for example, a nitride layer such as a silicon nitride layer. Other suitable metal materials are within the contemplated scope of disclosure.

The active LSI die 101 may also include a bulk silicon region 107 on the isolation layer 105. The active LSI die 101 may also include one or more active devices in the bulk silicon region 107. The active devices may include components within an electronic circuit that can control the flow of electricity. In particular, the devices may be capable of amplifying, switching, or generating electrical signals. The active devices may include, for example, transistors, operational amplifiers, integrated circuits (ICs), thyristors, voltage regulators, microprocessors, microcontrollers, etc.

The active devices may be located in one or more active regions in the active LSI die 101. In particular, the active regions of the active LSI die 101 may include an input/output interface (I/O interface) 51, a memory controller 52 and a physical layer 53. The memory controller 52 may be located in a central region of the active LSI die 101 between the I/O interface 51 and the physical layer 53. The I/O interface 51, the memory controller 52 and the physical layer 53 may be coupled to the lower contacts 103a by one or more through silicon vias (TSVs) 109. The I/O interface 51, the memory controller 52 and the physical layer 53 may therefore be coupled to the lower RDL structure 21 by the TSVs 109. The TSVs 109 may include, for example, one or more layers and may include metals, metal alloys, and/or other metal-containing compounds (e.g., Cu, Al, Mo, Co, Ru, W, TiN, TaN, WN, etc.).

The active LSI 101 may also include an upper dielectric layer 111 (e.g., passivation layer) on the bulk silicon region 107, and one or more upper contacts 111a in the upper dielectric layer 111. In particular, the upper dielectric layer 111 may be located on the I/O interface 51, the memory controller 52 and the physical layer 53. The upper dielectric layer 111 may also include, for example, silicon oxide, silicon nitride, low-k dielectric materials such as carbon-doped oxides, extremely low-k dielectric materials such as porous carbon doped silicon dioxide, a combination thereof or other suitable material. Other suitable metal materials are within the contemplated scope of disclosure.

The upper contacts 111a may be formed in the upper dielectric layer 111 so as to be electrically coupled to (e.g., contact) the I/O interface 51, the memory controller 52 and the physical layer 53. The upper contacts 111a may include metals, metal alloys, and/or other metal-containing compounds (e.g., Cu, Al, Mo, Co, Ru, W, TiN, TaN, WN, etc.). Other suitable metal materials are within the contemplated scope of disclosure.

The interposer molded portion 22 may also include one or more through interposer vias (TIVs) 206. The TIVs 206 may be formed in the molding material layer 227 adjacent the active LSI die 101. The TIVs 206 may extend over an entire thickness of the molding material layer 227. The TIVs 206 may contact one or more vias of the redistribution layers 12a in the lower RDL structure 21. The TIVs 206 may electrically couple the upper RDL structure 23 to the lower RDL structure 21. The first semiconductor die 141 may also be coupled to the lower RDL structure 21 through the upper RDL structure 23 and a TIV 206. The TIVs 206 may include metals, metal alloys, and/or other metal-containing compounds (e.g., Cu, Al, Mo, Co, Ru, W, TiN, TaN, WN, etc.). Other suitable metal materials are within the contemplated scope of disclosure.

The interposer molded portion 22 may also integrate additional elements, such as a stand-alone integrated passive devices (IPDs) (not shown). In at least one embodiment, the IPDs may be located in the molding material layer 227 underneath one or more of the semiconductor dies 140 (e.g., first semiconductor die 141, second semiconductor dies 142). The IPDs may help to support signal communication in the semiconductor module 120.

The upper RDL structure 23 may be formed over the active LSI die 101 and the molding material layer 227 of interposer molded portion 22. The upper RDL structure 23 may be substantially similar to the lower RDL structure 21. In particular, the upper RDL structure 23 may include a plurality of dielectric layers 13 (also referred to as polymer layers 13) and a plurality of redistribution layers 13a stacked alternately. The polymer layers 13 and redistribution layers 13a in the upper RDL structure 23 may be substantially similar to the polymer layers 12 and redistribution layers 12a in the lower RDL structure 23. The number of polymer layers 13 and/or the number of redistribution layers 13a in the upper RDL structure 23 are not limited by the disclosure.

The redistribution layers 13a may include metallic connection structures that provide electrical connection between nodes in the upper RDL structure 23. In at least one embodiment, the redistribution layers 13a may include a plurality of traces (lines) and a plurality of vias connecting the plurality traces to each other. The traces may be respectively located on the polymer layers 13, and may extend in the x-direction (first horizontal direction) and y-direction (second horizontal direction) on an upper surface of the polymer layers 13.

In at least one embodiment, one or more vias of the redistribution layers 13a may contact the TIVs 206 in the molding material layer 227. This may allow the upper RDL structure 23 to be electrically coupled to the lower RDL structure 21 through the TIVs 206. One or more vias of the redistribution layers 13a may also contact the upper contacts 111a of the active LSI die 101. This may allow the upper RDL structure 23 to be electrically coupled to the active LSI die 101. In particular, the upper RDL structure 23 may be electrically coupled through the upper contacts 111a to I/O interface 51, the memory controller 52 and the physical layer 53 of the active LSI die 101.

In at least one embodiment, the polymer layers 13 may include, for example, polyimide (PI), epoxy resin, acrylic resin, phenol resin, benzocyclobutene (BCB), polybenzoxazole (PBO), or any other suitable polymer-based dielectric material. In some embodiments, the redistribution layers 13a may include conductive materials (e.g., metals) such as copper, aluminum, nickel, titanium, a combination thereof, or other suitable conductive materials.

The semiconductor dies 140 may be mounted on the upper RDL section 23 of the interposer 20. The semiconductor dies 140 may be separated from one another by a first gap G1 that is located over the active LSI die 101. The first gap G1 may have a length in the x-direction in a range from 1 μm to 5000 μm.

Generally, a thickness in the z-direction of each of the semiconductor dies 140 (e.g., first semiconductor die 141, second semiconductor dies 142) may be substantially the same. The upper surfaces of each of the semiconductor dies 140 may be substantially coplanar (e.g., formed in the same x-y plane), and referred to collectively as the semiconductor die upper surface 140a (upper surface). In an embodiment in which the semiconductor dies 140 include upper surfaces that are not coplanar, the semiconductor die upper surface 140a may refer to the lowest upper surface of the upper surfaces of the semiconductor dies 140.

The semiconductor dies 140 may be connected to the upper RDL structure 23 of the interposer 20 by one or more interconnects 128 (e.g., microbumps). In at least one embodiment, each of the interconnects 128 may include an interposer bump portion 128a and a semiconductor die bump portion 128b. The interconnects 128 may also include a solder joint 128c connecting the interposer bump portion 128a to the semiconductor die bump portion 128b.

Each of the interposer bump portion 128a and a semiconductor die bump portion 128b may include a copper post and a barrier layer on the copper post. The semiconductor die bump portion 128b of the interconnects 128 may contact the semiconductor dies 140. The interposer bump portion 128a of the interconnects 128 may contact the via in the redistribution layers 13a of the upper RDL structure 23. The semiconductor dies 140 may, therefore, be electrically coupled to the redistribution layers 13a in the upper RDL structure 23 through the interconnects 128.

A semiconductor module underfill layer 129 may be formed (e.g., individually or connectively) under and around each of the semiconductor dies 140. The semiconductor module underfill layer 129 may also be formed around the interconnects 128. The semiconductor module underfill layer 129 may thereby fix each of the semiconductor dies 140 to the upper RDL structure 23 of the interposer 20. The semiconductor module underfill layer 129 may be formed of an epoxy-based polymeric material. Other materials may be used for the semiconductor module underfill layer 129 within the contemplated scope of disclosure.

Each of the semiconductor dies 140 may include, for example, a singular semiconductor die, a system on chip (SOC) die, or a system on integrated chips die, and may be implemented by chip on wafer on substrate technology or integrated fan-out on substrate technology. In particular, each of the semiconductor dies 140 may include, for example, a semiconductor chip or chiplet for a high performance computing (HPC) application, an artificial intelligence (AI) application, and a 5G cellular network application, a logic die (e.g., mobile application processor, microcontroller, etc.), or a memory die (e.g., high-bandwidth memory (HBM) die, hybrid memory cube (HMC), dynamic random access memory (DRAM) die, a Wide I/O die, a M-RAM die, a R-RAM die, an inverted AND (NAND) die, static random access memory (SRAM), etc.), a central processing unit (CPU) chip, graphics processing unit (GPU) chip, field-programmable gate array (FPGA) chip, networking chip, application-specific integrated circuit (ASIC) chip, artificial intelligence/deep neural network (AI/DNN) accelerator chip, etc., a co-processor, accelerator, an on-chip memory buffer, a high data rate transceiver die, a I/O interface die, an integrated passive device (IPD) die, a power management die (e.g., power management integrated circuit (PMIC) die), a radio frequency (RF) die, a sensor die, a micro-electro-mechanical-system (MEMS) die, a signal processing die (e.g., digital signal processing (DSP) die), a front-end die (e.g., analog front-end (AFE) die), a monolithic 3D heterogeneous chiplet stacking die, etc. Other dies are within the contemplated scope of this disclosure. In at least one embodiment, the first semiconductor die 141 may include a primary die (e.g., CPU die, GPU die, SOC die), and the second semiconductor dies 142 may each include an ancillary die (e.g., memory/SOC die, HBM die, etc.).

The semiconductor dies 140 may include a dielectric layer 143 (e.g., passivation layer) and one or more die bonding pads 143a in the dielectric layer 143. The dielectric layer 143 may include, for example, silicon oxide, silicon nitride, low-k dielectric materials such as carbon-doped oxides, extremely low-k dielectric materials such as porous carbon doped silicon dioxide, a combination thereof or other suitable material. Other suitable metal materials are within the contemplated scope of disclosure. The die bonding pads 143a may include metals, metal alloys, and/or other metal-containing compounds (e.g., Cu, Al, Mo, Co, Ru, W, TiN, TaN, WN, etc.). Other suitable metal materials are within the contemplated scope of disclosure.

As further illustrated in FIG. 1A, the first semiconductor die 141 may include a die-side I/O interface 61. The die-side I/O interface 61 may be coupled to one or more of the interconnects 128 by one or more of the die bonding pads 143a. The die-side I/O interface 61 may have a design and function that substantially corresponds to a design and function of the I/O interface 51 in the active LSI die 101. In at least one embodiment, each of the die-side I/O interface 61 and the I/O interface 51 in the active LSI die 101 may include a digital lite I/O interface. In at least one embodiment, the die-side I/O interface 61 may be located over the I/O interface 51 in the active LSI die 101. The die-side I/O interface 61 may, therefore, be efficiently coupled to the I/O interface 51 in the active LSI die 101 by data path DP1.

In addition, the second semiconductor dies 142 may include a die-side physical layer 63. The die-side physical layer 63 may be coupled to one or more of the interconnects 128 by one or more of the die bonding pads 143a. The die-side physical layer 63 may have a design and function that substantially corresponds to a design and function of the physical layer 53 in the active LSI die 101. In at least one embodiment, the second semiconductor dies 142 may include an HBM die, the die-side physical layer 63 may include a die-side HBM physical layer (HBM PHY), and the physical layer 53 in the active LSI die 101 may include an HBM physical layer (HBM PHY). In at least one embodiment, the die-side physical layer 63 may be located over the physical layer 53 of the active LSI die 101. The die-side physical layer 63 may, therefore, be efficiently coupled to the physical layer 53 of the active LSI die 101 by data path DP2.

The memory controller 52 in the active LSI die 101 may be coupled through the upper RDL structure 23 to the plurality of second semiconductor dies 142. In particular, the memory controller 52 may be coupled through the upper RDL structure 23 to the die-side I/O interface 61 in the first semiconductor die 141 and the die-side physical layer 63 in the second semiconductor die 142. An operation of the second semiconductor dies 142 may be controlled by the memory controller 52 (e.g., HBM memory controller) in the active LSI die 101. In at least one embodiment, the second semiconductor dies 142 may include a die-side memory controller (e.g., HBM memory controller) (not shown) and the memory controller 52 may operate in cooperation with the die-side memory controller.

The memory controller 52 may control an operation of the memory (e.g., HBM) in the second semiconductor dies 142 according to standard HBM memory protocol. In particular, the memory controller 52 may receive commands from the first semiconductor die 141, such as read requests and write requests, and in response to those commands activate or deactivate specific memory banks in the HBM of the second semiconductor dies 142. The memory controller 52 may manage a queue of commands received from the first semiconductor die 141. The memory controller 52 may prioritize the commands based on factors such as latency requirements, memory access patterns, and memory bank availability.

Once a command is selected for execution, the memory controller 52 may initiate the necessary operations to access the requested data from the memory banks in the HBM of the second semiconductor dies 142. In instances of a read operation, the memory controller 52 may send an activation command to the appropriate memory bank in the HBM of the second semiconductor dies 142, followed by a read command to retrieve the requested data. For write operations, the memory controller 52 may send an activation command, followed by a write command along with the data to be written to the HBM of the second semiconductor dies 142.

The memory controller 52 may use buffering and pipelining techniques to maximize memory bandwidth and minimize latency. The memory controller 52 may buffer incoming data from the HBM of the second semiconductor dies 142 to accommodate variations in memory access speed and ensure a steady flow of data to the first semiconductor die 141. The memory controller 52 may utilize pipelining to overlap the execution of multiple memory commands, enabling more efficient utilization of memory resources and reducing overall access latency.

The memory controller 52 may incorporate error detection (e.g., parity checking or cyclic redundancy check (CRC)) and correction mechanisms (e.g., using error correction codes (ECC)) to ensure data integrity. The memory controller 52 may also perform power and thermal management to optimize energy efficiency and prevent overheating.

The semiconductor module 120 may also include an upper molding material layer 127 formed around the semiconductor dies 140. The upper molding material layer 127 may also be formed on and around the semiconductor module underfill layer 129. The upper molding material layer 127 may have an outer sidewall that is substantially aligned with the outer sidewall of the interposer 20.

In at least one embodiment, the upper molding material layer 127 may be formed on sidewalls (inner sidewall and outer sidewall) of each of the semiconductor dies 140. The upper molding material layer 127 may be formed between and bonded to the sidewalls of each of the semiconductor dies 140. The upper molding material layer 127 may also be bonded to the chip-side surface of the upper RDL structure 23 the semiconductor module underfill layer 129.

As illustrated in FIG. 1A, the upper molding material layer 127 may include an upper surface that is substantially coplanar with the semiconductor die upper surface 140a. The upper surface of the upper molding material layer 127 may be substantially uniform (e.g., flat) or may alternatively include a recessed upper surface (not shown) that is recessed in the z-direction from the semiconductor die upper surface 140a. In at least one embodiment, the recessed upper surface may constitute an entirety of an upper surface of the upper molding material layer 127. In at least one embodiment, the recessed upper surface may constitute less than an entirety of an upper surface of the upper molding material layer 127.

In at least one embodiment, the upper molding material layer 127 may be formed of a curable material that may cure to form a hard, solid structure. The upper molding material layer 127 may include, for example, epoxy molding compound (EMC). In at least one embodiment, the upper molding material layer 127 may include a material that is substantially similar to the semiconductor module underfill layer 129, and or substantially similar to the molding material layer 227 in the interposer molded portion 22. In at least one embodiment, the upper molding material layer 127 may include a polymeric material and in particular, an epoxy-based polymeric material. Other suitable molding materials may be within the contemplated scope of disclosure.

In at least one embodiment, the upper molding material layer 127 may have a CTE that is substantially similar to a CTE of the interposer 20 (e.g., lower RDL structure 21, interposer molded portion 22, upper RDL structure 23). In at least one embodiment, the upper molding material layer 127 may include an added material (e.g., filler material) for improving a property of the upper molding material layer 127 (e.g., thermal conductivity, CTE, etc.). The added material may include, for example, metal powder, metal oxide powder, etc. Other materials in the upper molding material layer 127 are within the contemplated scope of the disclosure.

In at least one embodiment, the semiconductor module 120 may also include a backside metal layer (not shown) on the upper surface of the upper molding material layer 127. The backside metal layer may have a substantially uniform thickness throughout. In at least one embodiment, the backside metal layer may have a thickness in a range from 0.1 μm to 1.5 μm. The backside metal layer may include, for example, one or more layers of metal material such as copper, aluminum, nickel, titanium, a combination thereof or other suitable metals. In at least one embodiment, the backside metal layer may include one or more layers of aluminum, titanium, nickel vanadium (NiV) and gold.

Referring to FIG. 1B, in the top view of the semiconductor module 120, the active LSI die 101 may be located underneath the first semiconductor die 141, the second semiconductor dies 142 and the upper molding material layer 127. A location of the active LSI die 101 is, therefore, identified by shading and dashed lines in FIG. 1B.

As illustrated in FIG. 1B, the second semiconductor dies 142 may be located on the same side of the first semiconductor die 141. The second semiconductor dies 142 may be separated in the y-direction by a second gap G2. The second gap G2 may have a length in the y-direction substantially the same as the length of the first gap G1 in the x-direction. In particular, the second gap G2 may be in a range from 1 μm to 5000 μm.

The second semiconductor dies 142 may also be substantially aligned in the y-direction. The die-side physical layers 63 of the second semiconductor dies 142 may also be substantially aligned in the y-direction. The die-side physical layers 63 may also be arranged differently within the second semiconductor dies 142 so that the die-side physical layers 63 are proximate to each other.

The first semiconductor die 141 may be arranged so that the die-side I/O interface 61 is over the I/O interface 51 of the active LSI die 101. A length of the I/O interface 51 of the active LSI die 101 in the y-direction may be less than a length of the die-side I/O interface 61 in the first semiconductor die 141. A width of the I/O interface 51 of the active LSI die 101 in the x-direction may also be less than a width of the die-side I/O interface 61 in the first semiconductor die 141.

A length of the first semiconductor die 141 in the y-direction may be greater than a length of the I/O interface 51 of the active LSI die 101 in the y-direction. In at least one embodiment, the length of the first semiconductor die 141 may be no greater than 1.5 times the length of the I/O interface 51. The length of the first semiconductor die 141 may also be less than a combined length of the second semiconductor dies 142 in the y-direction. In at least one embodiment, the length of the first semiconductor die in the y-direction may be less than 80% of the combined length of the second semiconductor dies 142 in the y-direction.

The second semiconductor dies 142 may be arranged so that the physical layer 53 of the active LSI die 101 may straddle the second gap G2 between the second semiconductor dies 142. The memory controller 52 of the active LSI die 101 may be located at an intersection of the second gap G2 between the second semiconductor dies 142 and the first gap G1 between the first semiconductor die 141 and second semiconductor dies 142. The physical layer 53 of the active LSI die 101 may have a length in the y-direction that is sufficient to ensure that the die-side physical layers 63 in all of the second semiconductor dies 142 may be located over the physical layer 53. A length of the active LSI die 101 in the y-direction may therefore be equal to or greater than a combined length of the die-side physical layers 63 in all of the second semiconductor dies 142. A width of the physical layer 53 of the active LSI die 101 in the x-direction may be less than a width of the die-side physical layers 63 in the second semiconductor dies 142.

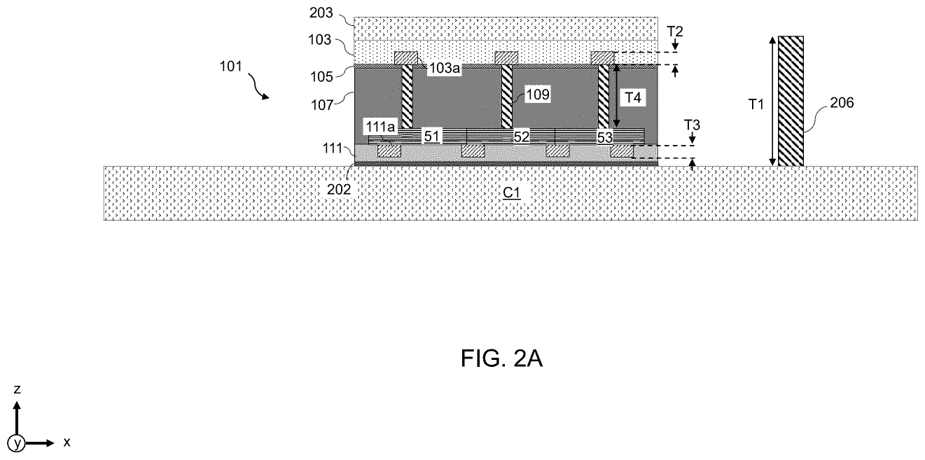

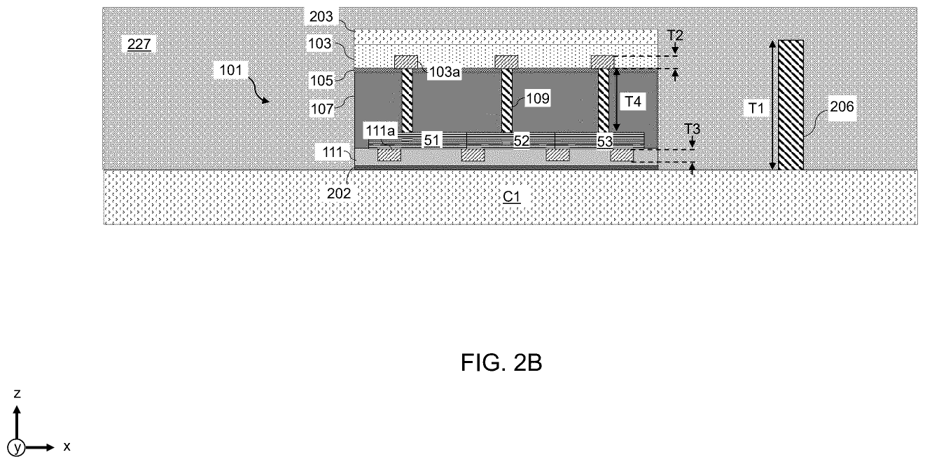

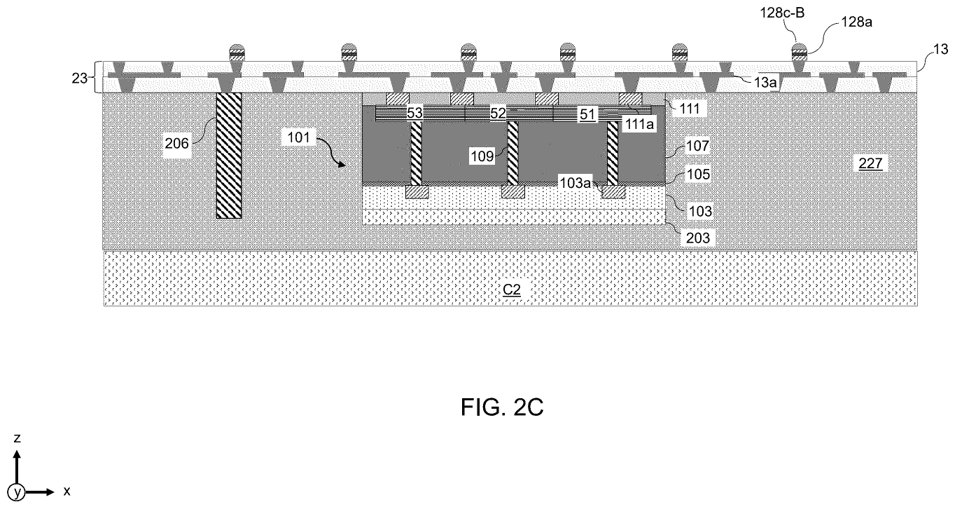

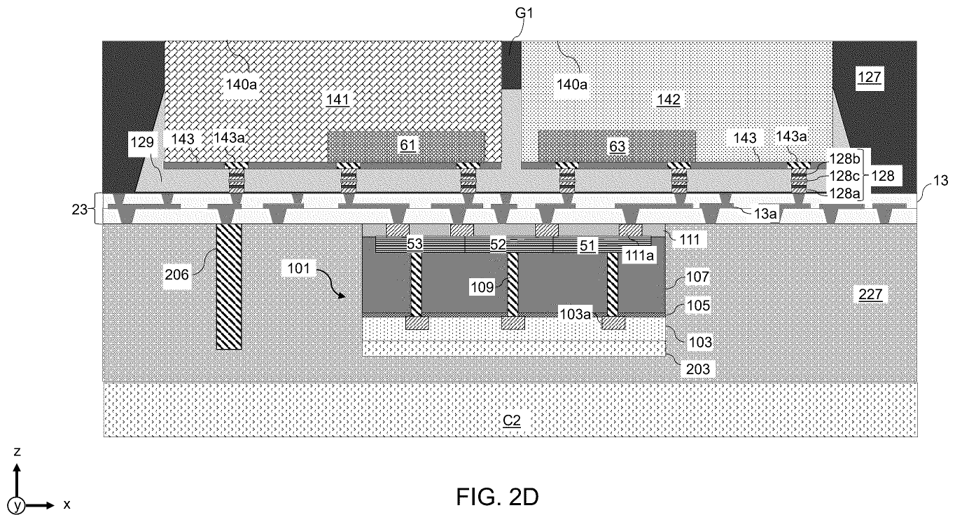

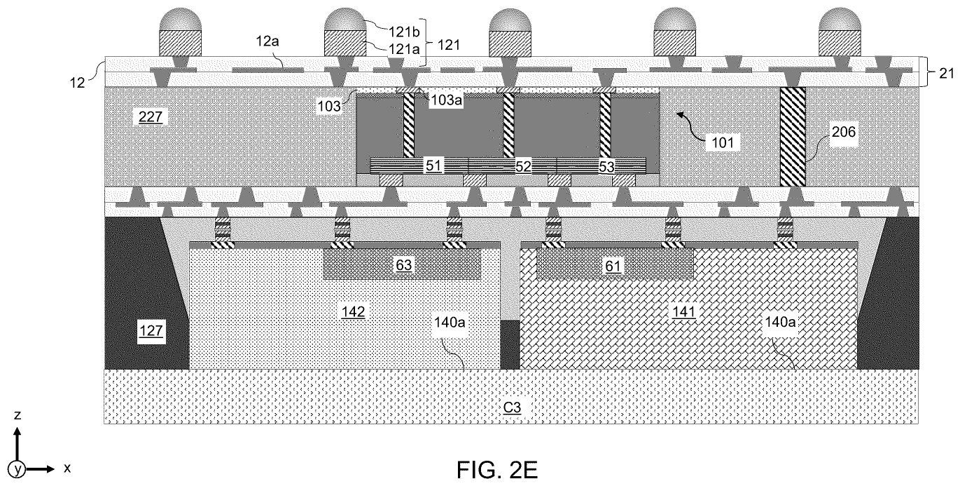

FIGS. 2A-2E illustrate various intermediate structures in a method of forming the semiconductor module 120 according to one or more embodiments. FIG. 2A is a vertical cross-sectional view of an intermediate structure including the active LSI die 101 and the TIV 206 on a first carrier substrate C1 (e.g., carrier wafer) according to one or more embodiments.

The TIV 206 may be formed on the first carrier substrate C1, for example, by an electroplating process. A seed layer of copper may first be deposited onto the first carrier substrate C1 using techniques such as physical vapor deposition (PVD) or chemical vapor deposition (CVD). Metal ions (e.g., copper ions) in a plating solution may then be deposited onto the seed layer under the influence of an electric current. The electroplating process may continue until the TIV 206 has attained a thickness T1 in a range from 135 μm to 155 μm (e.g., about 146 μm). Other methods of forming the TIV 206 are within the contemplated scope of disclosure.

The active LSI die 101 may then be placed on the first carrier substrate C1 adjacent to the TIV 206. The active LSI die 101 may be placed, for example, by an electromechanical pick-and-place (PnP) machine. At the time of placing the active LSI die 101 on the first carrier substrate C1, a supporting silicon layer 203 may be attached to the lower dielectric layer 103. Further, one or more elements of the active LSI die 101 may be different than in the completed semiconductor module 120. In particular, as illustrated in FIG. 2A, the lower dielectric layer 103 may have a thickness greater than a thickness T2 of the lower contacts 103a. The upper dielectric layer 111 may also have a thickness greater than a thickness T3 of the upper contacts 111a.

In at least one embodiment, the thickness T2 of the lower contacts 103a may be in a range from 30 μm to 55 μm (e.g., about 39 μm). The thickness of the lower dielectric layer 103 may be in a range from 70 μm to 100 μm. The thickness T3 of the upper contacts 111a may be in a range from 20 μm to 40 μm (e.g., about 27 μm). The thickness of the upper dielectric layer 111 may be in a range from 50 μm to 70 μm. A thickness T4 of the TSVs 109 may be in a range from 30 μm to 50 μm (e.g., about 40 μm).

The thicknesses of each of the I/O interface 51, the memory controller 52 and the physical layer 53 may be substantially the same. In at least one embodiment, the thicknesses of each of the I/O interface 51, the memory controller 52 and the physical layer 53 may be in a range from 5 μm to 15 μm (e.g., about 10 μm).

The first carrier substrate C1 may include a circular wafer or a rectangular wafer. The lateral dimensions (such as the diameter of a circular wafer or a side of a rectangular wafer) of the first carrier substrate C1 may be in a range from 100 mm to 500 mm, such as from 200 mm to 400 mm, although lesser and greater lateral dimensions may also be used. The first carrier substrate C1 may include a semiconductor substrate, an insulating substrate, or a conductive substrate. The first carrier substrate C1 may be transparent or opaque. A thickness of the first carrier substrate C1 may be sufficient to provide mechanical support to an array of interposers to be formed thereupon. For example, the thickness of the first carrier substrate C1 may be in a range from 60 microns to 1 mm, although lesser and greater thicknesses may also be used.

An adhesive layer 202 may be applied to the top surface of the first carrier substrate C1. In one embodiment, the first carrier substrate C1 may include an optically transparent material such as glass or sapphire. In this embodiment, the adhesive layer may include a light-to-heat conversion (LTHC) layer. The LTHC layer is a solvent-based coating applied using a spin coating method. The LTHC layer may form a layer that converts ultraviolet light to heat such that the LTHC layer loses adhesion. Alternatively, the adhesive layer may include a thermally decomposing adhesive material. For example, the adhesive layer may include an acrylic pressure-sensitive adhesive that decomposes at an elevated temperature. The debonding temperature of the thermally decomposing adhesive material may be in a range from 150° C. to 400° C. Other suitable thermally decomposing adhesive materials that decompose at other temperatures are within the contemplated scope of disclosure.

FIG. 2B is a vertical cross-sectional view of an intermediate structure including the molding material layer 227 according to one or more embodiments. Prior to forming the molding material layer 227, a die thinning process may be performed to thin the active LSI die 101. The die thinning process may be performed, for example, by grinding using a grinding wheel or abrasive disc. The active LSI die 101 may be thinned to have a thickness in a range from 180 μm to 220 μm (e.g., about 200 μm).

The molding material layer 227 (e.g., encapsulant layer) may then be formed on the first carrier substrate C1. As illustrated in FIG. 2B, the molding material layer 227 may be formed so as to cover the active LSI die 101 and the TIV 206. The molding material layer 227 may be formed by an over-molding process. The molding material layer 227 may be formed to have a thickness greater than a thickness of the active LSI die 101 and the TIV 206. In at least one embodiment, the molding material layer 227 may be formed to have a thickness in a range from 250 μm to 350 μm (e.g., about 300 μm).

The molding material layer 227 may include an epoxy polymer material (e.g., an epoxy molding compound (EMC). The molding material layer 227 may fill in the gaps between the active LSI die 101 and the TIV 206. The molding material layer 227 may encapsulate (e.g., in the x-direction and y-direction) the active LSI die 101 and the TIV 206. The molding material layer 227 may be formed, for example, by a deposition process such as CVD, PECVD, PVD, spin coating, lamination or other suitable deposition technique.

FIG. 2C is a vertical cross-sectional view of an intermediate structure including the upper RDL structure 23 on the molding material layer 227 according to one or more embodiments. After the upper molding material layer 127 has been cured, a second carrier substrate C2 may be attached to the intermediate structure of FIG. 2B. In particular, the second carrier substrate C2 may be attached to the upper surface of the molding material layer 227.

The intermediate structure of FIG. 2B may then be inverted and the first carrier substrate C1 may be detached (de-bonded) from the intermediate structure. The first carrier substrate C1 may be detached, for example, by deactivating the adhesive layer 202 adhering the first carrier substrate C1 to the intermediate structure. The adhesive layer 202 may be deactivated, for example, by a thermal anneal at an elevated temperature (e.g., for a thermally-deactivated adhesive material, or by exposing the adhesive layer to ultraviolet light (e.g., for an ultraviolet-deactivated adhesive material).

A planarization process may then be performed on the molding material layer 227, the upper dielectric layer 111, the upper contacts 111a and the TIV 206. The planarization process may be performed by chemical mechanical polishing (CMP), grinding, or other suitable process. As illustrated in FIG. 2C, the planarization process may be used to make an upper surface of the upper dielectric layer 111 substantially coplanar with an upper surface of the upper contacts 111a. An upper surface of the molding material layer 227 and the upper surface of the TIV 206 may also be made to be coplanar with the upper surface of the upper dielectric layer 111 and with an upper surface of the upper contacts 111a.

After performing the planarization process, the upper RDL structure 23 may be formed as illustrated in FIG. 2C. The upper RDL structure 23 may be formed by alternately forming a plurality of dielectric layers 13 and plurality of redistribution layers 13a. It should be noted that although FIG. 2C illustrates two dielectric layers 13, more or fewer dielectric layers 13 are contemplated by the present disclosure.

Each dielectric layer 13 may each be formed, for example, by depositing (e.g., by chemical vapor deposition (CVD), physical vapor deposition (PVD) or other suitable deposition technique) a layer of dielectric polymer material such as polyimide (PI), benzocyclobutene (BCB), or polybenzobisoxazole (PBO). Other suitable materials are within the contemplated scope of disclosure. The thickness of the layer of dielectric polymer material may be in a range from 4 microns to 60 microns, although lesser and greater thicknesses may also be used. The dielectric layer 13 may then be patterned by a photolithographic process to form via holes in the dielectric layer 13. The photolithographic process may include forming a patterned photoresist mask (not shown) on the layer of dielectric material, and etching (e.g., wet etching, dry etching, etc.) the exposed upper surface of the dielectric material through openings in the photoresist mask. The photoresist mask may be subsequently removed by ashing, dissolving the photoresist mask or by consuming the photoresist mask during the etch process.

A redistribution layer 13a (e.g., metal traces and metal vias) may then be formed on the dielectric layer 13. The redistribution layer 13a may be formed, for example, by depositing (e.g., by CVD, PVD or other suitable deposition technique) one or more layers of metal material such as copper, aluminum, nickel, titanium, a combination thereof or other suitable metals, on the dielectric layer 13 and in the vias holes formed by patterning the dielectric layer 13. The redistribution layer 13a may then be patterned by a photolithographic process. The photolithographic process may include forming a patterned photoresist mask (not shown) on the layer of metal material, and etching (e.g., wet etching, dry etching, etc.) the exposed upper surface of the metal material through openings in the photoresist mask. The photoresist mask may be subsequently removed by ashing, dissolving the photoresist mask or by consuming the photoresist mask during the etch process.

After the upper RDL structure 23 is formed, the interposer bump portion 128a of the interconnects 128 may be formed on an upper surface of the upper RDL structure 23. The interposer bump portion 128a (e.g., copper post, barrier layer, etc.) may be formed, for example, by performing one or more electroplating processes in a manner similar to the electroplating process described above for the TIV 206. The interposer bump portion 128a may be formed so as to contact a via portion of the redistribution layers 13a in the upper RDL structure 23.

A solder bump 128c-B may then be formed on the interposer bump portion 128a. The solder bump 128c-B may serve as a precursor to the solder joint 128c in the completed semiconductor module 120. The solder bump 128c-B may also be formed, for example, by an electroplating process. Other methods of forming the solder bump 128c-B are within the contemplated scope of disclosure.

FIG. 2D is a vertical cross-sectional view of an intermediate structure including the first semiconductor die 141 and second semiconductor die 142 on the upper RDL structure 23 according to one or more embodiments. Although not illustrated in FIG. 2D, all of the semiconductor dies 140 may be mounted concurrently on the upper RDL structure 23 in the same process.

Prior to attaching the first semiconductor die 141 and second semiconductor die 142 to the upper RDL structure 23, the semiconductor die bump portion 128b of the interconnects 128 may be formed on the first semiconductor die 141 and second semiconductor die 142. The first semiconductor die 141 and second semiconductor die 142 may then be positioned over the upper RDL structure 23 using an electromechanical PnP machine. The electromechanical PnP machine may then lower the first semiconductor die 141 and second semiconductor die 142 onto the upper RDL structure 23 so that the semiconductor die bump portion 128b contacts the solder bump 128c-B. The solder bump 128c-B may then be reflowed to form the solder joint 128c and complete the formation of the interconnects 128.

After the interconnects 128 are formed, the semiconductor module underfill layer 129 may be formed on the upper RDL structure 23. The semiconductor module underfill layer 129 may be applied, for example, by depositing and/or injecting an epoxy-based polymeric material onto the upper RDL structure 23. The epoxy-based polymeric material may be applied on the upper RDL structure 23 so as to be formed under the semiconductor dies 140 (e.g., first semiconductor die 141 and the second semiconductor die 142) and around the interconnects 128. In at least one embodiment, the epoxy-based polymeric material may fill substantially all of the gaps between the semiconductor dies 140 and the upper RDL structure 23. The semiconductor module underfill layer 129 may then be cured, for example, in a box oven for about 90 minutes at about 150° C. to provide the semiconductor module underfill layer 129 with sufficient stiffness and mechanical strength.

After the semiconductor module underfill layer 129 is formed, the upper molding material layer 127 may be formed around the semiconductor dies 140. The upper molding material layer 127 may be formed by dispensing a liquid molding material (e.g., EMC, epoxy molding material) around the semiconductor dies 140 by a suitable dispensing tool. The upper molding material layer 127 may be dispensed onto the intermediate structure so as to have a height greater than the height of the semiconductor die upper surface 140a.

In at least one embodiment, a dispensing of the molding material may be automated. In particular, various aspects of the dispensing process may be computer-controlled by a control system (e.g., electronic control system; central processing unit (CPU)). In at least one embodiment, a beginning of the dispensing of the molding material, a flow rate of the dispensing of the molding material, and a stopping of the dispensing of the molding material may be controlled by the control system. The control system may be programmed, for example, to dispense a predetermined amount of the molding material based on various input parameters.

After the upper molding material layer 127 has been adequately cured, the upper molding material layer 127 may be planarized so as to make the upper surface of the upper molding material layer 127 to be substantially coplanar with the semiconductor die upper surface 140a. The upper molding material layer 127 may be planarized, for example, by grinding, chemical mechanical polishing (CMP) or other suitable planarization technique.

FIG. 2E illustrates a vertical cross-sectional view of an intermediate structure including the plurality of C4 bumps 121, according to one or more embodiments. After the upper molding material layer 127 has been cured and planarized (e.g., by grinding, CMP, etc.), a second carrier substrate C2 may be detached (de-bonded) from the intermediate structure in FIG. 2D. attached to the intermediate structure of FIG. 2F. The second carrier substrate C2 may be detached in a manner similar to the manner used to detach the first carrier substrate C1. The intermediate structure may then be inverted and a third carrier substrate C3 may then be attached to the upper surface of the molding material layer 127 and the semiconductor die upper surface 140a of the semiconductor dies 140.

A planarization process may then be performed to planarize a surface of the molding material layer 127. The supporting silicon layer 203 may be removed from the lower dielectric layer 103 in the planarization process. The molding material layer 227 may be planarized so as to make the surface of the molding material layer 227 to be substantially coplanar with a surface of the TIV 206, a surface of the lower dielectric layer 103 and a surface of the lower contacts 103a. The upper molding material layer 127 may be planarized, for example, by grinding, chemical mechanical polishing (CMP) or other suitable planarization technique.

After the planarization process is performed, the lower RDL structure 21 may be formed on the surface of the molding material layer 227, the surface of the active LSI die 101 and the surface of the TIV 206. The lower RDL structure 21 may be formed in a manner similar to the manner of forming the upper RDL structure 23. In particular, the lower RDL structure 21 may be formed by alternately forming a plurality of dielectric layers 12 and plurality of redistribution layers 12a. It should be noted that although FIG. 2E illustrates two dielectric layers 12, more or fewer dielectric layers 12 are contemplated by the present disclosure.

Each dielectric layer 12 may each be formed, for example, by depositing (e.g., by chemical vapor deposition (CVD), physical vapor deposition (PVD) or other suitable deposition technique) a layer of dielectric polymer material such as polyimide (PI), benzocyclobutene (BCB), or polybenzobisoxazole (PBO). The dielectric layer 12 may then be patterned by a photolithographic process to form via holes in the dielectric layer 12. A redistribution layer 12a (e.g., metal traces and metal vias) may then be formed on the dielectric layer 12. The redistribution layer 12a may be formed, for example, by depositing (e.g., by CVD, PVD or other suitable deposition technique) one or more layers of metal material such as copper, aluminum, nickel, titanium, a combination thereof or other suitable metals, on the dielectric layer 12 and in the vias holes formed by patterning the dielectric layer 12. The redistribution layer 12a may then be patterned by a photolithographic process.

After the lower RDL structure 21 is formed, the plurality of C4 bumps 121 may then be formed on the intermediate structure. A metal pillar 121a (e.g., copper pillar) may be formed so as to contact vias of the lower RDL structure 21. The metal pillar 121a may be formed, for example, by an electroplating process. Other suitable processes may be used to form the metal pillar 121a. The solder bump 121b (e.g., SnAg solder bump) may then be formed on the metal pillar 121a. The solder bump 121b may also be formed by an electroplating process. Other suitable processes may be used to form the solder bump 121b.

After the formation of the plurality of C4 bumps are formed, the third carrier substrate C3 may be detached from the intermediate structure. A singulation process (e.g., dicing, sawing, etc.) may be performed. The singulation process may separate the semiconductor module 120 from surrounding wafer material and complete the formation of the semiconductor module 120.

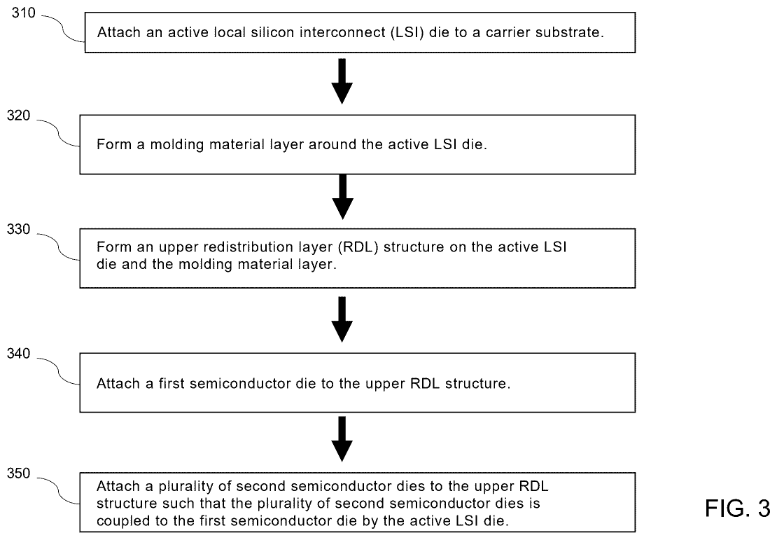

FIG. 3 is a flow chart illustrating a method of forming the semiconductor module 120 according to one or more embodiments. Step 310 includes attaching an active local silicon interconnect (LSI) die to a carrier substrate. Step 320 includes forming a molding material layer around the active LSI die. Step 330 includes forming an upper redistribution layer (RDL) structure on the active LSI die and the molding material layer. Step 340 includes attaching a first semiconductor die to the upper RDL structure. Step 350 includes attaching a plurality of second semiconductor dies to the upper RDL structure such that the plurality of second semiconductor dies is coupled to the first semiconductor die by the active LSI die.

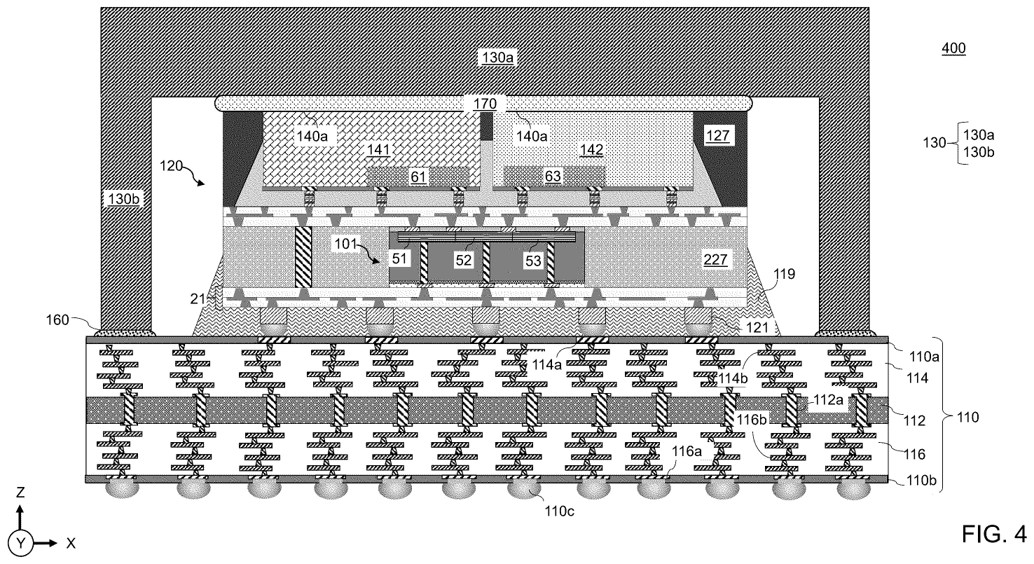

FIG. 4 is a vertical cross-sectional view of a package structure 400 according to one or more embodiments. As illustrated in FIG. 4, the package structure 400 may include a package substrate 110, the semiconductor module 120 on the package substrate 110, and a package lid 130 on the semiconductor module 120.

The package substrate 110 may include a cored or coreless substrate. In at least one embodiment, for example, the package substrate 110 may include a core 112, a package substrate upper dielectric layer 114 formed on the core 112 (e.g., a first side or chip-side of the package substrate 110), and a package substrate lower dielectric layer 116 formed on the core 112 (e.g., a second side or board-side of the package substrate 110). In particular, the package substrate 110 may include a build-up film substrate such as an Ajinomoto build-up film (ABF) substrate. That is, in at least one embodiment, each of the package substrate upper dielectric layer 114 and the package substrate lower dielectric layer 116 may be described as an ABF layer.

The core 112 may help to provide rigidity to the package substrate 110. The core 112 may include, for example, an epoxy resin such as a bismaleimide triazine epoxy (BT epoxy) and/or a woven glass laminate. The core 112 may alternatively or in addition include an organic material such as a polymer material. In particular, the core 112 may include a dielectric polymer material such as polyimide (PI), benzocyclo-butene (BCB), or polybenzobisoxazole (PBO). Other suitable dielectric materials are within the contemplated scope of disclosure.

The core 112 may include one or more through vias 112a. The through vias 112a may extend from a lower surface of the core 112 to an upper surface of the core 112. The through vias 112a may allow an electrical connection between the package substrate upper dielectric layer 114 and the package substrate lower dielectric layer 116. The through vias 112a may include, for example, one or more layers and may include metals, metal alloys, and/or other metal-containing compounds (e.g., Cu, Al, Mo, Co, Ru, W, TiN, TaN, WN, etc.). Other suitable metal materials are within the contemplated scope of disclosure.

The package substrate upper dielectric layer 114 may be formed on an upper surface of the core 112. The package substrate upper dielectric layer 114 may include a plurality of layers and, in particular, may include a build-up film (e.g., ABF). The package substrate upper dielectric layer 114 may also include an organic material such as a polymer material. In particular, the package substrate upper dielectric layer 114 may include a dielectric polymer material such as polyimide (PI), benzocyclobutene (BCB), or polybenzobisoxazole (PBO). Other suitable dielectric materials are within the contemplated scope of disclosure.

The package substrate upper dielectric layer 114 may include one or more package substrate upper bonding pads 114a on a chip-side surface of the package substrate upper dielectric layer 114. In particular, the package substrate upper bonding pads 114a may be exposed on the chip-side surface of the package substrate upper dielectric layer 114. The package substrate upper dielectric layer 114 may also include one or more metal interconnect structures 114b. The metal interconnect structures 114b may be connected to the package substrate upper bonding pads 114a and the through vias 112a in the core 112. The metal interconnect structures 114b may include metal layers (e.g., copper traces) and metal vias connecting the metal layers. The package substrate upper bonding pads 114a and the metal interconnect structures 114b may include, for example, one or more layers and may include metals, metal alloys, and/or other metal-containing compounds (e.g., Cu, Al, Mo, Co, Ru, W, TiN, TaN, WN, etc.). Other suitable metal materials are within the contemplated scope of disclosure.

A package substrate upper passivation layer 110a may be formed on the chip-side surface of the package substrate upper dielectric layer 114. The package substrate upper passivation layer 110a may partially cover the package substrate upper bonding pads 114a. The upper passivation layer 110a may include silicon oxide, silicon nitride, low-k dielectric materials such as carbon-doped oxides, extremely low-k dielectric materials such as porous carbon doped silicon dioxide, a combination thereof or other suitable material.

The package substrate lower dielectric layer 116 may be formed on a lower surface of the core 112. The package substrate lower dielectric layer 116 may also include a plurality of layers and, in particular, may include a build-up film (e.g., ABF). The package substrate lower dielectric layer 116 may also include an organic material such as a polymer material. In particular, the package substrate lower dielectric layer 116 may include a dielectric polymer material such as polyimide (PI), benzocyclobutene (BCB), or polybenzobisoxazole (PBO). Other suitable dielectric materials are within the contemplated scope of disclosure.

The package substrate lower dielectric layer 116 may include one or more package substrate lower bonding pads 116a on a board-side surface of the package substrate lower dielectric layer 116. In particular, the package substrate lower bonding pads 116a may be exposed on the board-side surface of the package substrate lower dielectric layer 116. The package substrate lower dielectric layer 116 may also include one or more metal interconnect structures 116b. The metal interconnect structures 116b may be connected to the package substrate lower bonding pads 116a and the through vias 112a in the core 112. The metal interconnect structures 116b may include metal layers (e.g., copper traces) and metal vias connecting the metal layers. The package substrate lower bonding pads 116a and the metal interconnect structures 116b may include, for example, one or more layers and may include metals, metal alloys, and/or other metal-containing compounds (e.g., Cu, Al, Mo, Co, Ru, W, TiN, TaN, WN, etc.). Other suitable metal materials are within the contemplated scope of disclosure.

A package substrate lower passivation layer 110b may be formed on the board-side surface of the package substrate lower dielectric layer 116. The package substrate lower passivation layer 110b may partially cover the package substrate lower bonding pads 116a. The package substrate lower passivation layer 110b may include silicon oxide, silicon nitride, low-k dielectric materials such as carbon-doped oxides, extremely low-k dielectric materials such as porous carbon doped silicon dioxide, a combination thereof or other suitable material.

A ball-grid array (BGA) including a plurality of solder balls 110c may be formed on the board-side surface of the package substrate lower dielectric layer 116. The solder balls 110c may allow the package structure 400 to be securely mounted on a substrate such as a printed circuit board (PCB) and electrically coupled to the PCB substrate. The solder balls 110c may contact the package substrate lower bonding pads 116a, respectively. The solder balls 110c may therefore be electrically connected to the package substrate upper bonding pads 114a by way of metal interconnect structures 116b, the through vias 112a and the metal interconnect structures 114b.

The semiconductor module 120 may be connected to the package substrate 110 by the C4 bumps 121 on the board-side surface of the lower RDL structure 21. In particular, the C4 bumps 121 may be bonded (e.g., using solder reflow, compression bonding, thermocompression bonding, etc.) to the package substrate upper bonding pads 114a of the package substrate 110. As illustrated in FIG. 4, the package substrate 110 may have a length in the x-direction that is less than a length of the semiconductor module 120 in the x-direction. The package substrate 110 may also have a width in the y-direction that is less than a width of the semiconductor module 120 in the y-direction.

A package underfill layer 119 may be formed between the semiconductor module 120 and the package substrate 110. The package underfill layer 119 may help to bond the semiconductor module 120 to the package substrate 110. The package underfill layer 119 may be substantially similar to the semiconductor module underfill layer 129 in the semiconductor module 120. The package underfill layer 119 may be formed under the lower RDL structure 21 and around the C4 bumps 121. The package underfill layer 119 may also be formed on a sidewall of the lower RDL structure 21 and on a sidewall of the molding material layer 227. The package underfill layer 119 may be formed of an epoxy-based polymeric material. Other materials may be used for the package underfill layer 119 within the contemplated scope of disclosure.

The package structure 400 may further include a thermal interface material (TIM) layer 170 on the semiconductor module 120. The TIM layer 170 may be located on the upper molding material layer 127 of the semiconductor module 120.

The TIM layer 170 may include, for example, a TIM paste, a gel TIM, graphite TIM, metal TIM, solder TIM and a carbon nanotube TIM. In at least one embodiment, the TIM layer 170 may include a film-type TIM layer. In at least one embodiment, the TIM layer 170 may include an indium base, silver base and/or solder base. Other types of TIMs are within the contemplated scope of this disclosure. In at least one embodiment, the TIM layer 170 may have a thickness (e.g., a greatest thickness in the z-direction) in a range from 100 μm to 300 μm.

The TIM layer 170 may be formed on the semiconductor module 120 to dissipate of heat generated during operation of the package structure 400 (e.g., operation of the semiconductor dies 140). The TIM layer 170 may be attached to the semiconductor module 120, for example, by a thermally conductive adhesive. The TIM layer 170 may have a low bulk thermal impedance and high thermal conductivity. The bond-line-thickness (BLT) (e.g., a distance between the package lid 130 and the semiconductor module 120) may be less than about 100 μm, although greater or lesser distances may be used.

The package lid 130 may be located on the TIM layer 170 and connected to the package substrate 110. The package lid 130 may include a package lid plate portion 130a over the semiconductor module 120. The package lid plate portion 130a may contact at least a portion of the TIM layer 170. In one or more embodiments, the package lid plate portion 130a may directly contact an entire upper surface of the TIM layer 170. The TIM layer 170 may be compressed between the package lid plate portion 130a and the semiconductor module 120.

The package lid 130 may also include a package lid foot portion 130b connected to the package lid plate portion 130a. The package lid foot portion 130b may be integrally formed with the package lid plate portion 130a. The package lid foot portion 130b may be fixed to the package substrate 110 by an adhesive layer 160.

The package lid 130 may be formed, for example, of metal, ceramic or polymer material. The package lid 130 may have a plate shape (e.g., planar shape) and be substantially parallel to an upper surface of the package substrate 110. The package lid 130 may extend, for example, in an x-y plane in FIG. 4. The package lid foot portion 130b may include an outer sidewall that is substantially aligned with an outer sidewall of the upper molding material layer 127. The package lid plate portion 130a may include a central portion that is substantially aligned in the z-direction with a central portion of the semiconductor module 120. The package lid plate portion 130a may include an upper surface and a bottom surface that are substantially planar.

The adhesive layer 160 may bond the package lid foot portion 130b to the package substrate 110. A thickness of the adhesive layer 160 may be in a range from 50 μm to 200 μm. The adhesive layer 160 may include, for example, a silicone adhesive (e.g., containing aluminum oxide, zinc oxide, resin, etc.) or an epoxy adhesive. Other suitable adhesives may be used.

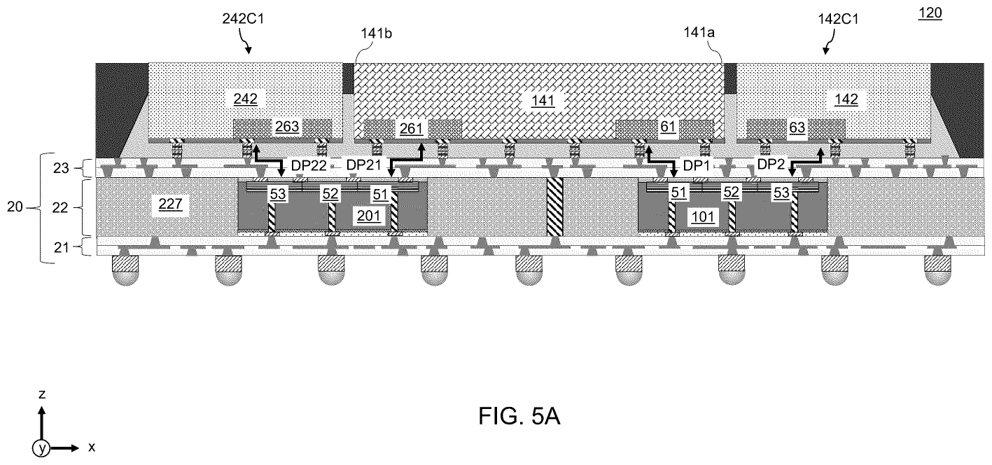

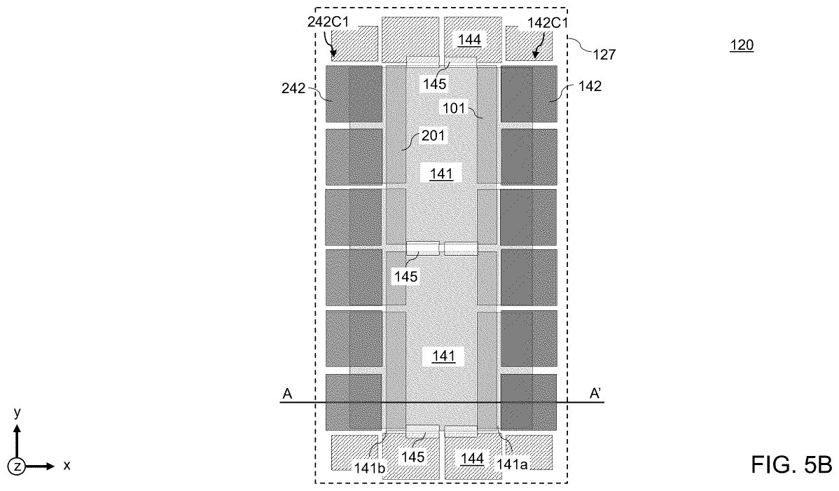

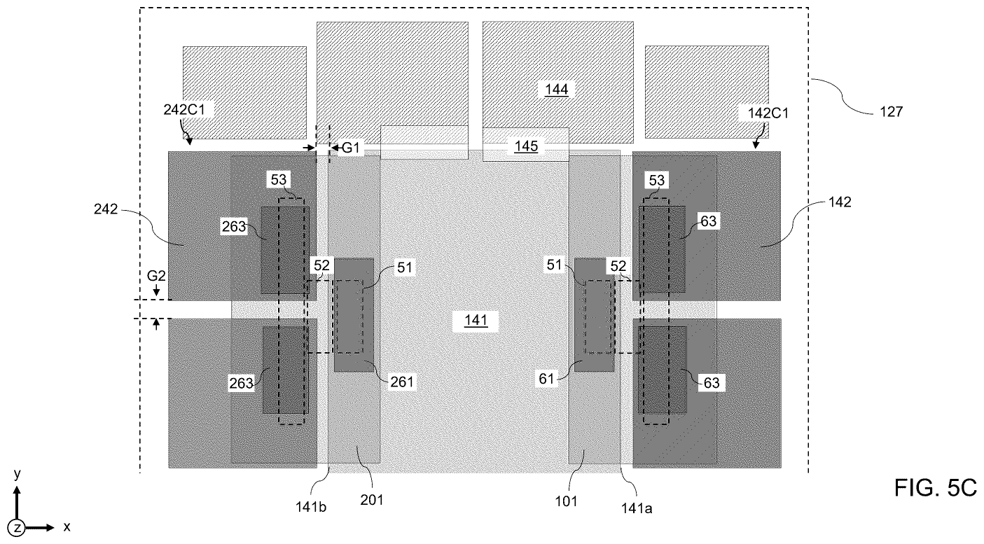

FIGS. 5A-5C are various views of the semiconductor module 120 having a first alternative configuration according to one or more embodiments. In particular, FIG. 5A is a vertical cross-sectional view of the semiconductor module 120 having the first alternative configuration according to one or more embodiments. FIG. 5B is a plan view (e.g., top-down view) of the semiconductor module 120 having the first alternative configuration according to one or more embodiments. The vertical cross-sectional view in FIG. 5A may be along the line A-A′ in FIG. 5B. FIG. 5C is a detailed plan view (e.g., top-down view) of a portion of the semiconductor module 120 having the first alternative configuration according to one or more embodiments.

As illustrated in FIG. 5A, in the first alternative configuration, the semiconductor module 120 may include an array of second semiconductor dies 142 on the first side 141a of the first semiconductor die 141, and an array of second semiconductor dies 242 on the second side 141b of the first semiconductor die 141. In particular, the semiconductor module 120 may include a right column 142C1 of second semiconductor dies 142 on a right side 141a of the first semiconductor die 141 and a left column 242C1 of second semiconductor dies 242 on a left side 141b of the first semiconductor die 141 opposite the right side 141a of the first semiconductor die 141. The second semiconductor dies 242 may have a structure and function substantially the same as the structure and function of the second semiconductor dies 142. In at least one embodiment, each of the second semiconductor dies 142 and the second semiconductor dies 242 may include HBM dies.

The first semiconductor die 141 may also include a die-side I/O interface 261 on the left side 141b of the first semiconductor die 141. The die-side I/O interface 261 may have a structure and function substantially the same as the die-side I/O interface 61. In at least one embodiment, each of the die-side I/O interface 261 and the die-side I/O interface 61 may include a digital lite I/O interface.

The second semiconductor die 242 may include a die-side physical layer 263 adjacent the left side 141b of the first semiconductor die 141. The die-side physical layer 263 may have a structure and function substantially the same as the die-side physical layer 63 in the second semiconductor die 142. In at least one embodiment, each of the die-side physical layer 263 and the die-side physical layer 63 may include an HBM physical layer (HBM PHY).

The semiconductor module 120 may also include an active LSI die 201 on the left side 141b of the first semiconductor die 141. The active LSI die 201 may have a structure and function substantially the same as the active LSI die 101. In particular, the active LSI die 201 may include an I/O interface 51, a memory controller 52 and a physical layer 53. In at least one embodiment, the I/O interface 51 may include a digital lite I/O interface and the physical layer 53 may include an HBM physical layer (HBM PHY).

An operation between the die-side I/O interface 261, die-side physical layer 263 and the active LSI die 201 may be substantially the same as operation between the die-side I/O interface 61, die-side physical layer 63 and the active LSI die 101. In particular, the die-side I/O interface 261 may be located over the I/O interface 51 in the active LSI die 201 so that the die-side I/O interface 261 may be efficiently coupled to the I/O interface 51 by data path DP21. The die-side physical layer 263 may be located over the physical layer 53 of the active LSI die 201 so that the die-side physical layer 263 may be efficiently coupled to the physical layer 53 by data path DP22. The memory controller 52 may be coupled through the upper RDL structure 23 to the die-side I/O interface 261 in the first semiconductor die 141 and the die-side physical layer 263 in the second semiconductor die 242. An operation of the second semiconductor die 242 (e.g., HBM die) may be controlled by the memory controller 52 (HBM memory controller) in the active LSI die 201.

Referring again to FIG. 5B, in the first alternative configuration, the semiconductor module 120 may include a plurality of first semiconductor dies 141. The plurality of first semiconductor dies 141 may be arranged in a column extending in the y-direction. The second semiconductor dies 141 may be arranged in a column extending in the y-direction on the first side 141a of the first semiconductor dies 141. The second semiconductor dies 242 may be arranged in a column extending in the y-direction on the second side 141b of the first semiconductor dies 141.

The semiconductor module 120 may also include third semiconductor dies 144. The third semiconductor dies 144 may be substantially the same the second semiconductor dies 142, 242 (e.g., ancillary dies, HBM dies, etc.). The third semiconductor dies 144 may be coupled to the first semiconductor die 141 (e.g., through the upper RDL structure 23). However, the third semiconductor dies 144 may not be coupled to the active LSI dies 101, 201.

The semiconductor module 120 may also include connecting structures 145. The connecting structures 145 may include, for example, connecting dies. The connecting structures 145 may connect the third semiconductor dies 144 to the first semiconductor dies 141. The connecting structures 145 may also connect one of the first semiconductor dies 141 to another one of the first semiconductor dies 141. The connecting structures 145 may be located, for example, in the interposer molded portion 22 adjacent the active LSI dies 101, 201.

Referring again to FIG. 5C, in the first alternative configuration the second semiconductor dies 142 and active LSI die 101 may have a physical arrangement on the first side 141a of the first semiconductor die 141 which is substantially the same as described above with respect to FIG. 1B.

On the second side 141b of the first semiconductor die 141 the physical arrangement of the second semiconductor dies 242 and active LSI die 201 may be substantially a mirror image of the physical arrangement of the semiconductor dies 142 and active LSI die 101 on the first side 141a of the first semiconductor die 141. In particular, the die-side I/O interface 261 may be over the I/O interface 51 of the active LSI die 201. A length of the I/O interface 51 of the active LSI die 101 in the y-direction may be less than a length of the die-side I/O interface 61 in the first semiconductor die 141. A width of the I/O interface 51 of the active LSI die 201 in the x-direction may also be less than a width of the die-side I/O interface 261 in the first semiconductor die 141.

The second semiconductor dies 242 may be arranged so that the physical layer 53 of the active LSI die 201 may straddle the second gap G2 between the second semiconductor dies 242. The memory controller 52 of the active LSI die 201 may be located at an intersection of the second gap G2 between the second semiconductor dies 242 and the first gap G1 between the first semiconductor die 141 and second semiconductor dies 242. The physical layer 53 of the active LSI die 201 may have a length in the y-direction that is sufficient to ensure that the die-side physical layers 263 in all of the second semiconductor dies 242 may be located over the physical layer 53. A length of the active LSI die 201 in the y-direction may therefore be equal to or greater than a combined length of the die-side physical layers 263 in all of the second semiconductor dies 242. A width of the physical layer 53 of the active LSI die 201 in the x-direction may be less than a width of the die-side physical layers 263 in the second semiconductor dies 242.

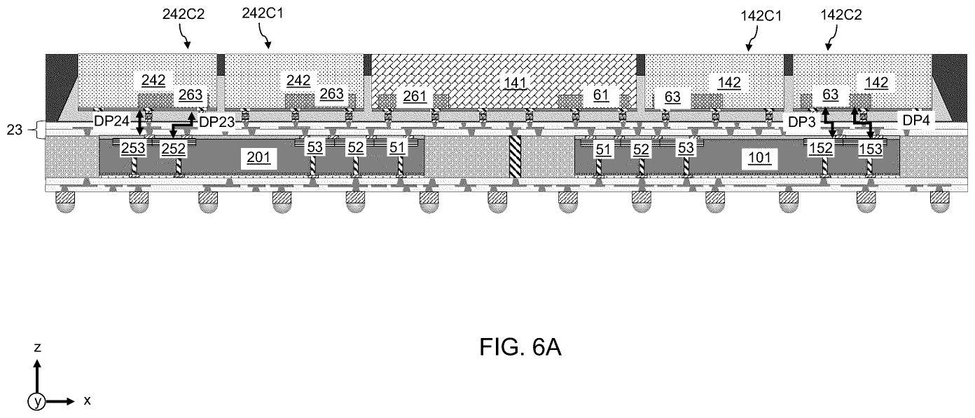

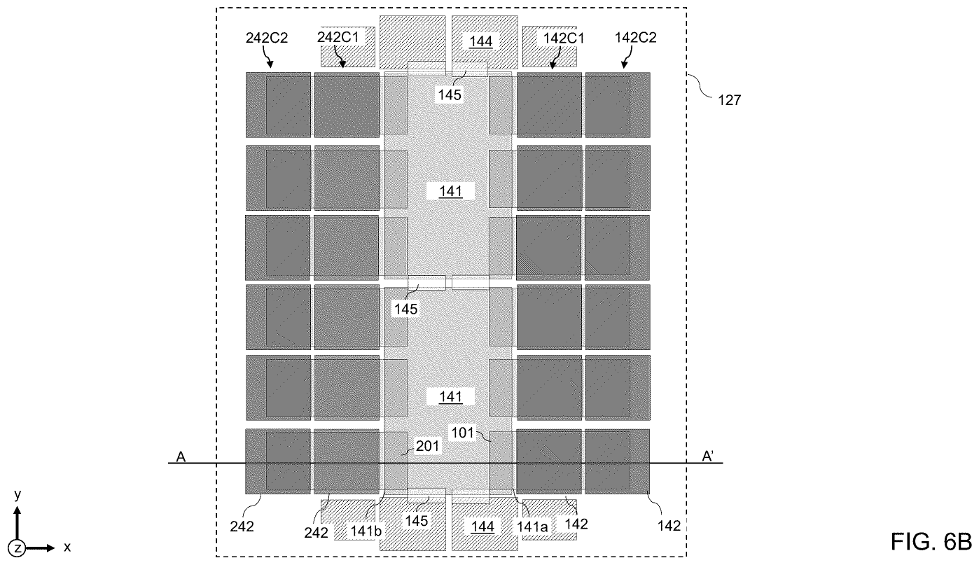

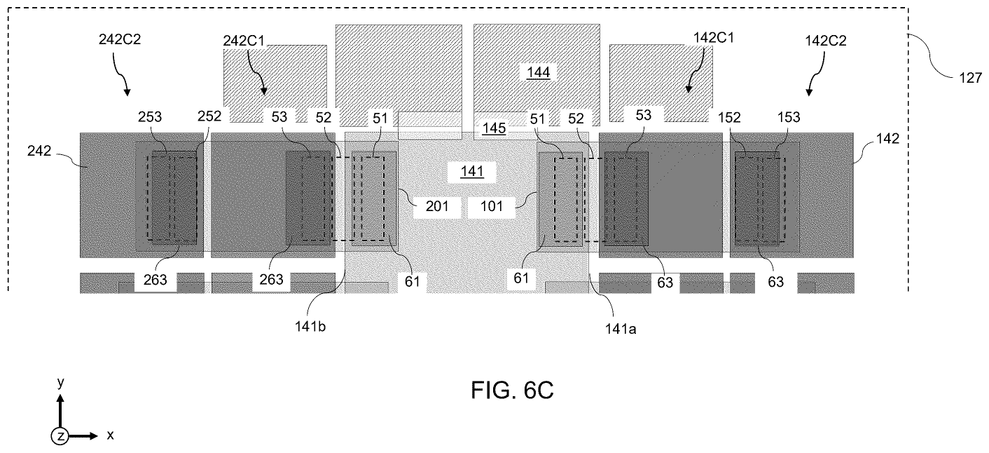

FIGS. 6A-6C are various views of the semiconductor module 120 having a second alternative configuration according to one or more embodiments. In particular, FIG. 6A is a vertical cross-sectional view of the semiconductor module 120 having the second alternative configuration according to one or more embodiments. FIG. 6B is a plan view (e.g., top-down view) of the semiconductor module 120 having the second alternative configuration according to one or more embodiments. The vertical cross-sectional view in FIG. 6A may be along the line A-A′ in FIG. 6B. FIG. 6C is a detailed plan view (e.g., top-down view) of a portion of the semiconductor module 120 having the second alternative configuration according to one or more embodiments. It should be noted that although only two columns are shown in FIGS. 6A-6C, more than two columns may be included in the semiconductor module 120 having the second alternative configuration.

Referring to FIG. 6A, the second alternative configuration the semiconductor module 120 may be substantially similar to the first alternative configuration in FIG. 5A. However, the second alternative configuration may additionally include a second right column 142C2 of the second semiconductor dies 142 adjacent the first right column 142C1. The second alternative configuration may also additionally include a second left column 242C2 of the second semiconductor dies 242 adjacent the first left column 242C1.

In addition, in the second alternative configuration, the active LSI die 101 may extend in the x-direction to be located over the second semiconductor dies 142 in both the first right column 142C1 and the second right column 142C2. The I/O interface 51 in the active LSI die 101 may operate as an interface (e.g., digital lite I/O interface) for the second semiconductor dies 142 in both the first right column 142C1 and the second right column 142C2.

The active LSI die 101 may also include a second memory controller 152 substantially the same as the memory controller 52. The second memory controller 152 may be coupled to the die-side physical layer 63 in the second semiconductor die 142 in the second right column 142C2 of second semiconductor dies 142. The second memory controller 152 may control an operation of the second semiconductor die 142 in the second right column 142C2 of second semiconductor dies 142. Further, die-side physical layer 63 of the second semiconductor die 142 in the second right column 142C2 of second semiconductor dies 142 may be located over the memory controller 152 in the active LSI die 101 so that the die-side physical layer 63 may be efficiently coupled to the memory controller 152 by data path DP3.

The active LSI die 101 may also include a second physical layer 153 (e.g., second HBM PHY) substantially the same as the physical layer 53. The second physical layer 153 may be coupled to the die-side physical layer 63 in the second semiconductor die 142 in the second right column 142C2 of second semiconductor dies 142. The die-side physical layer 63 may also be located over the physical layer 153 of the active LSI die 101 so that the die-side physical layer 63 may be efficiently coupled to the physical layer 153 by data path DP4.

In addition, in the second alternative configuration the active LSI die 201 may extend in the x-direction to be located over the second semiconductor dies 242 in both the first left column 242C1 and the second left column 242C2. The I/O interface 51 in the active LSI die 201 may operate as an interface (e.g., digital lite I/O interface) for the second semiconductor dies 242 in both the first left column 242C1 and the second left column 242C2.

The active LSI die 201 may also include a second memory controller 252 substantially the same as the memory controller 52. The second memory controller 252 may be coupled to the die-side physical layer 263 in the second semiconductor die 242 in the second left column 242C2 of second semiconductor dies 242. The second memory controller 252 may control an operation of the second semiconductor die 242 in the second left column 242C2 of second semiconductor dies 242. Further, the die-side physical layer 263 of the second semiconductor die 242 in the second left column 242C2 of second semiconductor dies 142 may be located over the memory controller 252 in the active LSI die 201 so that the die-side physical layer 263 may be efficiently coupled to the memory controller 252 by data path DP23.

The active LSI die 201 may also include a second physical layer 253 (e.g., second HBM PHY) substantially the same as the physical layer 53. The second physical layer 253 may be coupled to the die-side physical layer 263 in the second semiconductor die 242 in the second left column 242C2 of second semiconductor dies 242. The die-side physical layer 263 may also be located over the physical layer 253 of the active LSI die 201 so that the die-side physical layer 263 may be efficiently coupled to the physical layer 253 by data path DP24.

As illustrated in FIG. 6B, in the second alternative configuration, a width of the active LSI 101 in the x-direction may be substantially similar to a combined width of the second semiconductor dies 142 in the first right column 142C1 and second right column 142C2. In addition, a width of the active LSI 201 in the x-direction may be substantially similar to a combined width of the second semiconductor dies 242 in the first left column 242C1 and second left column 242C2.

Further, in contrast to first alternative configuration in FIG. 5B where the active LSI die 101 may extend lengthwise in the y-direction, in the second alternative configuration the active LSI die 101 may extend lengthwise in the x-direction. Thus, the number of active LSI dies 101 in the semiconductor module 120 may be equal to the number of rows of second semiconductor dies 142 on the first side 141a of the first semiconductor die 141. The active LSI die 201 may also extend lengthwise in the x-direction. Thus, the number of active LSI dies 201 in the semiconductor module 120 may be equal to the number of rows of second semiconductor dies 242 on the second side 141b of the first semiconductor die 141.

The number of columns of second semiconductor dies 142 on the first side 141a of the first semiconductor die 141 may be the same or different than the number of columns of second semiconductor dies 242 on the second side 141b of the first semiconductor die 141. The number of rows of second semiconductor dies 142 on the first side 141a of the first semiconductor die 141 may be the same or different than the number of rows of second semiconductor dies 242 on the second side 141b of the first semiconductor die 141.

Referring again to FIG. 6C, a physical arrangement of the second semiconductor dies 142 and active LSI die 101 on the first side 141a of the first semiconductor die 141 will be described. The physical arrangement of the second semiconductor dies 242 and active LSI die 201 on the second side 141b of the first semiconductor die 141 may be substantially a mirror image of the physical arrangement of the semiconductor dies 142 and active LSI die 101 on the first side 141a of the first semiconductor die 141. Therefore, the description of the physical arrangement of the second semiconductor dies 142 and active LSI die 101 on the first side 141a of the first semiconductor die 141 may be equally applicable to the physical arrangement of the second semiconductor dies 242 and active LSI die 201 on the second side 141b of the first semiconductor die 141.

As illustrated in FIG. 6C, the die-side I/O interface 61 may be over the I/O interface 51 of the active LSI die 101. A length of the I/O interface 51 of the active LSI die 101 in the y-direction may be less than a length of the die-side I/O interface 61 in the first semiconductor die 141. A width of the I/O interface 51 of the active LSI die 101 in the x-direction may also be less than a width of the die-side I/O interface 61 in the first semiconductor die 141.

The die-side physical layer 63 may be over the physical layer 53 of the active LSI die 101. The physical layer 53 of the active LSI die 101 may have a length in the y-direction that is less than a length of the die-side physical layer 63 in the second semiconductor die 142 in the first column 142C1 of second semiconductor dies 142. A width of the physical layer 53 of the active LSI die 101 in the x-direction may be less than a width of the die-side physical layer 63 in the second semiconductor die 142 in the first right column 142C1 of second semiconductor dies 142.

The die-side physical layer 63 in the second semiconductor die 142 in the second column 142C2 may be substantially aligned in the x-direction with the die side physical layer 63 in the semiconductor die 142 in the first right column 142C1. The die-side physical layer 63 in the second right column 142C2 of second semiconductor dies 142 may be located over the memory controller 152 and the physical layer 153 in the active LSI die 101. The physical layer 153 of the active LSI die 101 may have a length in the y-direction that is less than a length of the die-side physical layer 63 in the second semiconductor die 142 in the second right column 142C2. A width of the physical layer 153 of the active LSI die 101 in the x-direction may also be less than a width of the die-side physical layer 63 in the second semiconductor die 142 in the second right column 142C2.

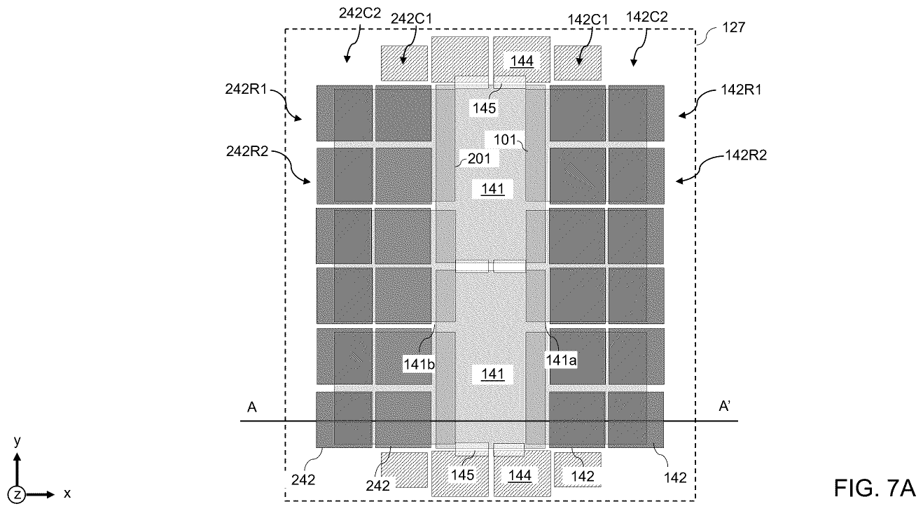

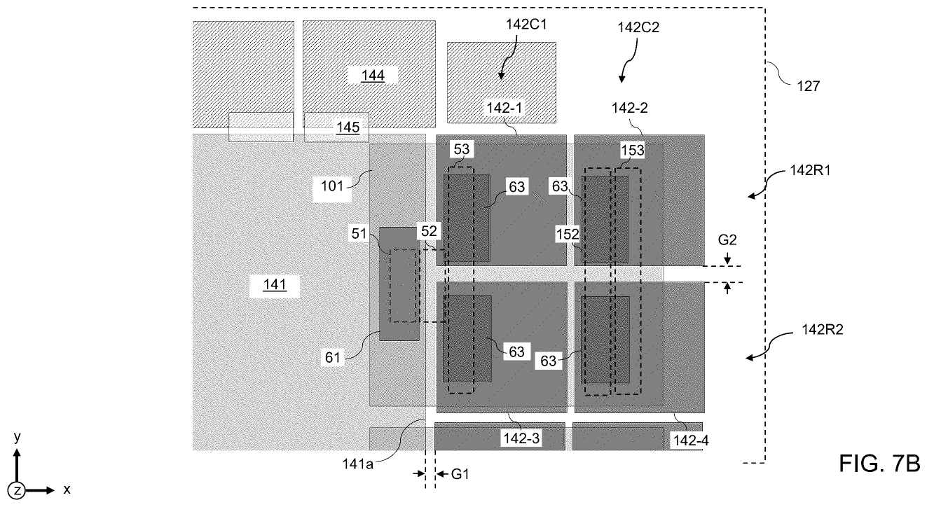

FIGS. 7A-7B are various views of the semiconductor module 120 having a third alternative configuration according to one or more embodiments. FIG. 7A is a plan view (e.g., top-down view) of the semiconductor module 120 having the third alternative configuration according to one or more embodiments. FIG. 7B is a detailed plan view (e.g., top-down view) of a portion of the semiconductor module 120 having the third alternative configuration according to one or more embodiments. It should be noted that although only two columns are shown in FIGS. 7A-7B, more than two columns may be included in the semiconductor module 120 having the third alternative configuration. It should also be noted that the vertical cross-sectional view along the line A-A′ in FIG. 7A may be substantially similar to the vertical cross-sectional view of the second alternative configuration in in FIG. 6A.

As illustrated in FIG. 7A, the third alternative configuration of the semiconductor module 120 may be substantially similar to the second alternative configuration in FIG. 6A-6C. However, in the third alternative configuration the active LSI die 101 may be extended in the y-direction so as to cover second semiconductor dies 142 in both a plurality of columns of the second semiconductor dies 142 (first right column 142C1 and second right column 142C2) and a plurality of rows of the second semiconductor dies 142 (e.g., first right row 142R1 and second right row 142R2 in FIG. 7A). The active LSI die 201 may also be extended in the y-direction so as to cover second semiconductor dies 242 in both a plurality of columns of the second semiconductor dies 242 (first left column 242C1 and second left column 242C2) and a plurality of rows of the second semiconductor dies 242 (e.g., first left row 242R1 and second left row 242R2 in FIG. 7A).

Referring to FIG. 7B, a physical arrangement of the second semiconductor dies 142 and active LSI die 101 on the first side 141a of the first semiconductor die 141 will be described. The physical arrangement of the second semiconductor dies 242 and active LSI die 201 on the second side 141b of the first semiconductor die 141 may be substantially a mirror image of the physical arrangement of the semiconductor dies 142 and active LSI die 101 on the first side 141a of the first semiconductor die 141. Therefore, the description of the physical arrangement of the second semiconductor dies 142 and active LSI die 101 on the first side 141a of the first semiconductor die 141 may be equally applicable to the physical arrangement of the second semiconductor dies 242 and active LSI die 201 on the second side 141b of the first semiconductor die 141. Further, it should be noted that with respect to first right column 142C1 of the second semiconductor dies 142, the description of the active LSI die 101 pertaining to FIG. 1B may be applicable to the third alternative configuration in FIG. 7B.

As illustrated in FIG. 7B, the active LSI die 101 may be formed over second semiconductor die 142-1 and second semiconductor die 142-2 in first right row 142R1, and over second semiconductor die 142-3 and second semiconductor die 142-4 in second right row 142R2. The second semiconductor die 142-1 and second semiconductor die 142-3 may be separated from the first semiconductor die 141 by a first gap G1. The second semiconductor dies 142 in first right row 142R1 may be separated from the second semiconductor dies 142 in second right row 142R2 in the y-direction by a gap G2.

The active LSI die 101 may have a length in the y-direction that is substantially the same as a combined length of the second semiconductor dies in first right row 142R1 and second right row 142R2 plus a length of the gap G2. The first semiconductor die 141 may be arranged so that the die-side I/O interface 61 is substantially aligned with the gap G2.

With respect to first right column 142C1, the I/O interface 51, memory controller 52 and physical layer 53 of the active LSI die 101 may also be substantially aligned with the gap G2. The memory controller 52 may be located at an intersection of first gap G1 and gap G2. The physical layer 53 in the active LSI die 101 may straddle the gap G2. The physical layer 53 in the active LSI die 101 may have a length in the y-direction greater than a length of the I/O interface 51 and a length of the memory controller 52. In particular, the length of the physical layer 53 may be sufficient to be under the die-side physical layer 63 in second semiconductor die 142-1 and under the die-side physical layer 63 in second semiconductor die 142-3.

With respect to second right column 142C2, the memory controller 152 and the physical layer 153 have substantially the same length in the y-direction. The memory controller 152 and the physical layer 153 may be substantially aligned with the physical layer 53 and straddle the gap G2. Each of the memory controller 152 and physical layer 153 may be under the die-side physical layer 63 in second semiconductor die 142-2 and under the die-side physical layer 63 in second semiconductor die 142-4.

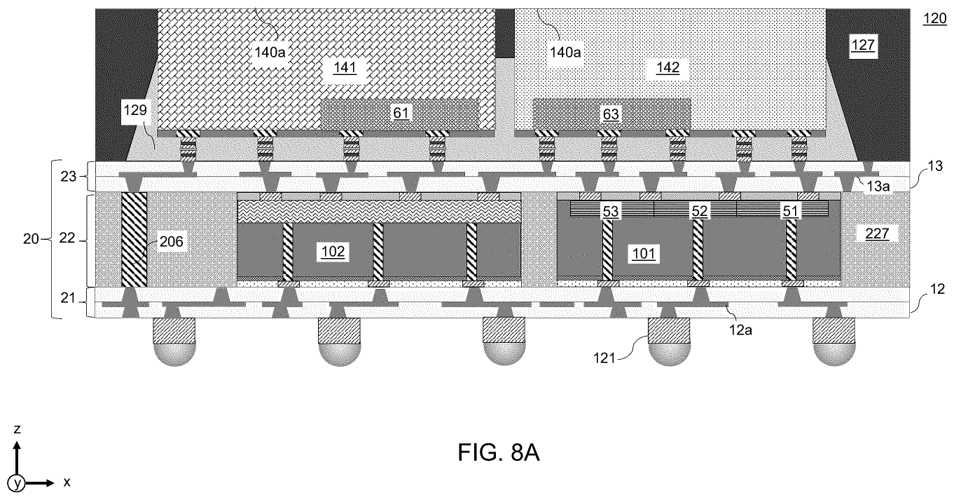

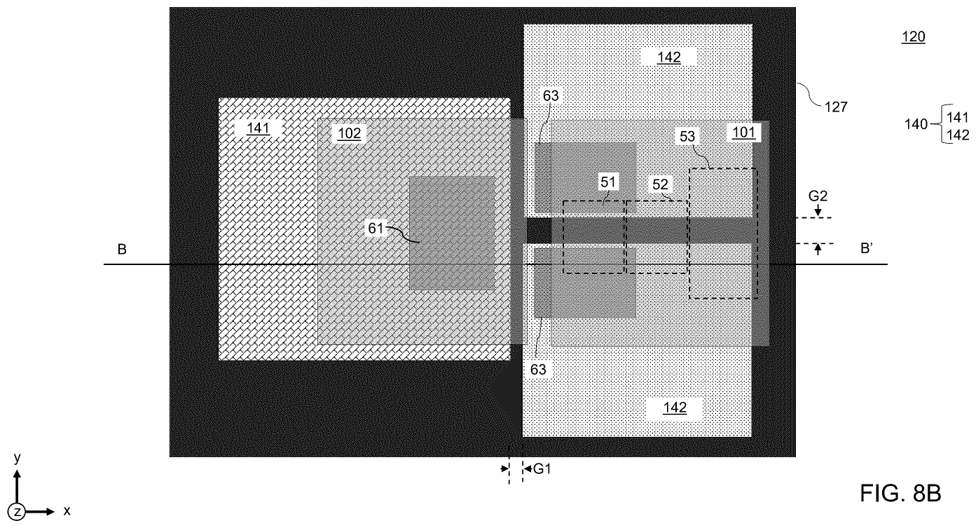

FIGS. 8A-8B provide different views of the semiconductor module 120 having a fourth alternative configuration according to one or more embodiments. FIG. 8A is a vertical cross-sectional view of the semiconductor module 120 having the fourth alternative configuration according to one or more embodiments. FIG. 8B illustrates a plan view (e.g., top-down view) of the semiconductor module 120 having the fourth alternative configuration according to one or more embodiments. The vertical cross-sectional view in FIG. 8A may be along the line B-B′ in FIG. 8B.

As illustrated in FIG. 8A, the semiconductor module 120 having the fourth alternative configuration may be substantially similar as the semiconductor module 120 in FIGS. 1A-1B. However, the semiconductor module 120 having a fourth alternative configuration may additionally include a passive LSI die 102 adjacent the active LSI die 101 in the molding material layer 227 of the interposer 20.

As illustrated in FIG. 8A, the active LSI die 101 may be located under the second semiconductor die 142 and the passive LSI die 102 may be located under the first semiconductor die 141. In particular, the die-side physical layer 63 of the second semiconductor die 142 may be located over the physical layer 53 of the active LSI die 101. The die-side physical layer 63 of the second semiconductor die 142 may coupled to the physical layer 53 through the upper RDL structure 23.

As further illustrated in FIG. 8A, the first semiconductor die 141 and the plurality of second semiconductor dies 142 may be coupled to the passive LSI die 102. In particular, the die-side physical layer 63 of the second semiconductor die 142 may also be coupled to the passive LSI die 102 through the upper RDL structure 23. The die-side I/O interface 61 in the first semiconductor die 141 may also be coupled to the passive LSI die 102 through the upper RDL structure 23.

As illustrated in FIG. 8B, the first semiconductor die 141 may be arranged so that the die-side I/O interface 61 is over the passive LSI die 102. The second semiconductor dies 142 may be arranged so that the die-side physical layers 63 in the second semiconductor dies 142 may be located over the I/O interface 51 of the active LSI die 101 and over a portion of the memory controller 52 of the active LSI die 101. Each of the I/O interface 51, the memory controller 52 and the physical layer 53 of the active LSI die 101 may straddle the gap G2 between the second semiconductor dies 142.

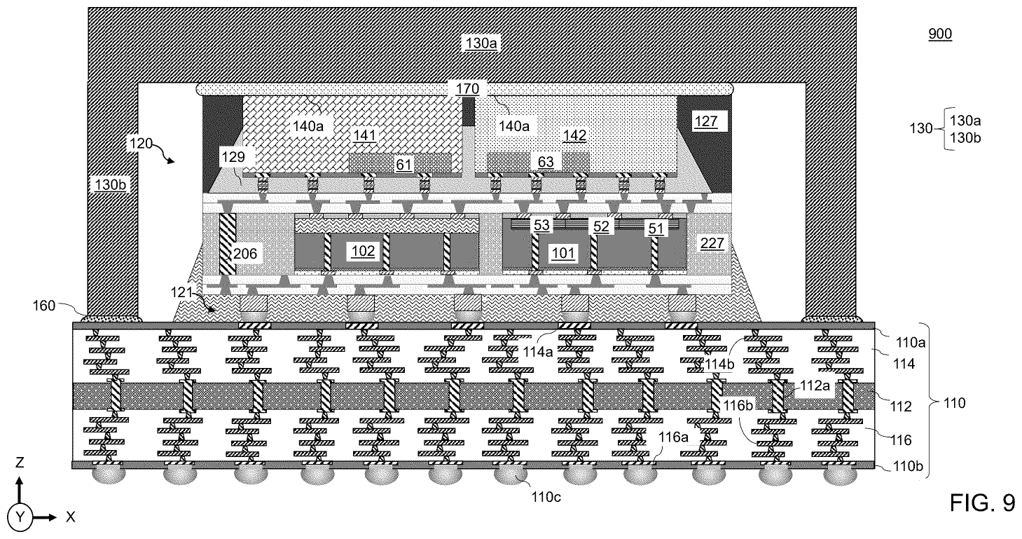

FIG. 9 is a vertical cross-sectional view of a package structure 900 including the semiconductor module 120 having the fourth alternative configuration according to one or more embodiments. The package structure 900 may have a structure substantially similar to the package structure 400 and the discussion with respect to the package structure 400 in FIG. 4 may also be applicable to the package structure 900 in FIG. 9.

Referring to FIGS. 1A-9, a semiconductor module 120, may include an interposer 20 including an active local silicon interconnect (LSI) die 101, 201 including an active device, a first semiconductor die 141 on the interposer 20, and a plurality of second semiconductor dies 142, 242 adjacent the first semiconductor die 141 on the interposer 20 and coupled to the first semiconductor die 141 by the active LSI die 101, 201.

In one embodiment, the first semiconductor die 141 and the plurality of second semiconductor dies 142, 242 may be located over the active LSI die 101, 201. In one embodiment, the first semiconductor die 141 may include one of a system on chip (SoC) die, central processing unit (CPU) die or graphics processing unit (GPU) die, and the plurality of second semiconductor dies 142, 242 may include a high bandwidth memory (HBM) die. In one embodiment, the active LSI die 101, 201 may include an HBM physical layer 53, 153, 253 and the plurality of second semiconductor dies 142, 242 may include an HBM physical layer 63, 263 coupled to the HBM physical layer 53, 153, 253 of the active LSI die 101, 201. In one embodiment, the HBM physical layer 63, 263 of the plurality of second semiconductor dies 142, 242 may be located over the HBM physical layer 53, 153, 253 of the active LSI die 101, 201. In one embodiment, the active LSI die 101, 201 may further include an input/output (I/O) interface and an I/O interface 61 of the first semiconductor die 141 may be coupled to the I/O interface 51 of the active LSI die 101, 201. In one embodiment, the I/O interface 61 of the first semiconductor die 141 may be located over the I/O interface 51 of the active LSI die 101, 201. In one embodiment, the active LSI die 101, 201 may further include a memory controller 52, 152, 252 for controlling an operation of the plurality of second semiconductor dies 142, 242. In one embodiment, the memory controller 52, 152, 252 may be located between the I/O interface 51 of the active LSI die 101, 201 and the HBM physical layer 53, 153, 253 of the active LSI die 101, 201. In one embodiment, the interposer 20 may include an interposer molded portion 22, wherein the active LSI die 101, 201 may be located in the interposer molded portion 22, and an upper redistribution layer (RDL) structure on the interposer molded portion 22. In one embodiment, the HBM physical layer 63, 263 of the plurality of second semiconductor dies 142, 242 may be coupled to the HBM physical layer 53, 153, 253 of the active LSI die 101, 201 through the upper RDL structure 23, and the I/O interface 61 of the first semiconductor die 141 may be coupled to the I/O interface 51 of the active LSI die 101, 201 through the upper RDL structure 23. In one embodiment, the interposer 20 may further include a lower RDL structure 21 on a side of the interposer molded portion 22 opposite the upper RDL structure 23. In one embodiment, the active LSI die 101, 201 may include a plurality of through silicon vias (TSVs) 109 and the memory controller 52, 152, 252, the I/O interface 51 of the active LSI die 101, 201, and the HBM physical layer 53, 153, 253 of the active LSI die 101, 201 may be coupled to the lower RDL structure 21 by the plurality of TSVs 109. In one embodiment, the plurality of second semiconductor dies 142, 242 may include an array of the plurality of second semiconductor dies 142, 242 including a first right column 142C1 of the plurality of second semiconductor dies 142, 242 and a first left column 242C1 of the plurality of second semiconductor dies 142, 242 located over the active LSI die 101, 201 and coupled to the first semiconductor die 141 by the active LSI die 101, 201, and a second right column 142C2 of the plurality of second semiconductor dies 142, 242 and a second left column 242C2 of the plurality of second semiconductor dies 142, 242 respectively located adjacent the first right column 142C1 of the plurality of second semiconductor dies 142, 242 and first left column 242C1 of the plurality of second semiconductor dies 142, 242, wherein the second right column 142C2 of the plurality of second semiconductor dies 142, 242 and the second left column 242C2 of the plurality of second semiconductor dies 142, 242 may be located over the active LSI die 101, 201 and coupled to the first semiconductor die 141 by the active LSI die 101, 201.

Referring again to FIGS. 1A-9, a method of forming a semiconductor module 120 may include attaching an active local silicon interconnect (LSI) die 101, 201 to a carrier substrate C1, forming a molding material layer 227 around the active LSI die 101, 201, forming an upper redistribution layer (RDL) structure 23 on the active LSI die 101, 201 and the molding material layer 227, attaching a first semiconductor die 141 to the upper RDL structure 23, and attaching a plurality of second semiconductor dies 142, 242 to the upper RDL structure 23 such that the plurality of second semiconductor dies 142, 242 may be coupled to the first semiconductor die 141 by the active LSI die 101, 201.

In one embodiment method, the attaching of the first semiconductor die 141 to the upper RDL structure 23 may include attaching one of a system on chip (SoC) die, central processing unit (CPU) die or graphics processing unit (GPU) die to the upper RDL structure 23, and the attaching of the plurality of second semiconductor dies 142, 242 to the upper RDL structure 23 may include attaching a plurality of high bandwidth memory (HBM) dies to the upper RDL structure 23. In one embodiment method, the attaching of the first semiconductor die 141 to the upper RDL structure 23 may include locating the first semiconductor die 141 over the active LSI die 101, 201, and the attaching of the plurality of second semiconductor dies 142, 242 to the upper RDL structure 23 may include locating the plurality of second semiconductor dies 142, 242 over the active LSI die 101, 201. In one embodiment method, the attaching of the first semiconductor die 141 to the upper RDL structure 23 may include locating an I/O interface 61 of the first semiconductor die 141 over an I/O interface 51 of the active LSI die 101, 201 and coupling the I/O interface 61 of the first semiconductor die 141 to the I/O interface 51 of the active LSI die 101, 201 through the upper RDL structure 23, and wherein the attaching of the plurality of second semiconductor dies 142, 242 to the upper RDL structure 23 may include locating an HBM physical layer 63, 263 of the plurality of second semiconductor dies 142, 242 over an HBM physical layer 53, 153, 253 of the active LSI die 101, 201 and coupling the HBM physical layer 63, 263 of the plurality of second semiconductor dies 142, 242 to the HBM physical layer 53, 153, 253 of the active LSI die 101, 201 through the upper RDL structure 23. In one embodiment method, the attaching of the plurality of second semiconductor dies 142, 242 to the upper RDL structure 23 may include attaching an array of the plurality of second semiconductor dies 142, 242 to the upper RDL structure 23, including attaching a first right column 142C1 of the plurality of second semiconductor dies 142, 242 and a first left column 242C1 of the plurality of second semiconductor dies 142, 242 located over the active LSI die 101, 201 and coupled to the first semiconductor die 141 by the active LSI die 101, 201, and attaching a second right column 142C2 of the plurality of second semiconductor dies and a second left column 242C2 of the plurality of second semiconductor dies 142, 242 respectively located adjacent the first right column 142C1 of the plurality of second semiconductor dies and the first left column 242C1 of the plurality of second semiconductor dies 142, 242, wherein the second right column 142C2 of the plurality of second semiconductor dies and the second left column 242C2 of the plurality of second semiconductor dies 142, 242 may be located over the active LSI die 101, 201 and coupled to the first semiconductor die 141 by the active LSI die 101, 201.

Referring again to FIGS. 1A-9, a semiconductor module 120 may include an interposer 20 including a lower redistribution layer (RDL) structure 21, an interposer molded portion 22 on the lower RDL structure 21 including a through interposer via (TIV) 206 and an active local silicon interconnect (LSI) die 101, 201 including an active device and including a memory controller 52, 152, 252, and an upper RDL structure 23 on the interposer molded portion 22, a first semiconductor die 141 on the interposer 20 and coupled to the lower RDL structure 21 through the upper RDL structure 23 and the TIV 206, and a plurality of second semiconductor dies 142 adjacent the first semiconductor die 141 on the interposer 20 and coupled to the memory controller 52, 152, 252 in the active LSI die 101. In at least one embodiment, the interposer 20 may further include a passive LSI die 102, and the first semiconductor die 141 and the plurality of second semiconductor dies 142 are coupled to the passive LSI die 102.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor module, comprising:
an interposer including an active local silicon interconnect (LSI) die;
a first semiconductor die on the interposer; and
a plurality of second semiconductor dies adjacent the first semiconductor die on the interposer and coupled to the first semiconductor die through the active LSI die.

2. The semiconductor module of claim 1, wherein the first semiconductor die and the plurality of second semiconductor dies are located over the active LSI die.

3. The semiconductor module of claim 1, wherein the first semiconductor die comprises one of a system on chip (SoC) die, central processing unit (CPU) die or graphics processing unit (GPU) die, and the plurality of second semiconductor dies comprises a high bandwidth memory (HBM) die.

4. The semiconductor module of claim 1, wherein the active LSI die comprises an HBM physical layer and the plurality of second semiconductor dies comprises an HBM physical layer coupled to the HBM physical layer of the active LSI die.

5. The semiconductor module of claim 4, wherein the HBM physical layer of the plurality of second semiconductor dies is located over the HBM physical layer of the active LSI die.

6. The semiconductor module of claim 4, wherein the active LSI die further comprises an input/output (I/O) interface and an I/O interface of the first semiconductor die is coupled to the I/O interface of the active LSI die.

7. The semiconductor module of claim 6, wherein the I/O interface of the first semiconductor die is located over the I/O interface of the active LSI die.

8. The semiconductor module of claim 6, wherein the active LSI die further comprises a memory controller for controlling an operation of the plurality of second semiconductor dies.

9. The semiconductor module of claim 8, wherein the memory controller is located between the I/O interface of the active LSI die and the HBM physical layer of the active LSI die.

10. The semiconductor module of claim 8, wherein the interposer comprises:
a interposer molded portion, wherein the active LSI die is located in the interposer molded portion; and
an upper redistribution layer (RDL) structure on the interposer molded portion.

11. The semiconductor module of claim 10, wherein the HBM physical layer of the plurality of second semiconductor dies is coupled to the HBM physical layer of the active LSI die through the upper RDL structure, and the I/O interface of the first semiconductor die is coupled to the I/O interface of the active LSI die through the upper RDL structure.

12. The semiconductor module of claim 10, wherein the interposer further comprises a lower RDL structure on a side of the interposer molded portion opposite the upper RDL structure.

13. The semiconductor module of claim 1, wherein the plurality of second semiconductor dies comprises an array of the plurality of second semiconductor dies comprising:
a first right column of the plurality of second semiconductor dies and a first left column of the plurality of second semiconductor dies located over the active LSI die and coupled to the first semiconductor die by the active LSI die; and
a second right column of the plurality of second semiconductor dies and a second left column of the plurality of second semiconductor dies respectively located adjacent the first right column of the plurality of second semiconductor dies and the first left column of the plurality of second semiconductor dies, wherein the second right column of the plurality of second semiconductor dies and the second left column of the plurality of second semiconductor dies are located over the active LSI die and coupled to the first semiconductor die by the active LSI die.

14. A method of forming a semiconductor module, the method comprising:
attaching an active local silicon interconnect (LSI) die to a carrier substrate;
forming a molding material layer around the active LSI die;
forming an upper redistribution layer (RDL) structure on the active LSI die and the molding material layer;
attaching a first semiconductor die to the upper RDL structure; and
attaching a plurality of second semiconductor dies to the upper RDL structure such that the plurality of second semiconductor dies is coupled to the first semiconductor die by the active LSI die.

15. The method of claim 14, wherein the attaching of the first semiconductor die to the upper RDL structure comprises attaching one of a system on chip (SoC) die, central processing unit (CPU) die or graphics processing unit (GPU) die to the upper RDL structure, and the attaching of the plurality of second semiconductor dies to the upper RDL structure comprises attaching a plurality of high bandwidth memory (HBM) dies to the upper RDL structure.

16. The method of claim 14, wherein the attaching of the first semiconductor die to the upper RDL structure comprises locating the first semiconductor die over the active LSI die, and the attaching of the plurality of second semiconductor dies to the upper RDL structure comprises locating the plurality of second semiconductor dies over the active LSI die.

17. The method of claim 14, wherein the attaching of the first semiconductor die to the upper RDL structure comprises locating an I/O interface of the first semiconductor die over an I/O interface of the active LSI die and coupling the I/O interface of the first semiconductor die to the I/O interface of the active LSI die through the upper RDL structure, and
wherein the attaching of the plurality of second semiconductor dies to the upper RDL structure comprises locating an HBM physical layer of the plurality of second semiconductor dies over an HBM physical layer of the active LSI die and coupling the HBM physical layer of the plurality of second semiconductor dies to the HBM physical layer of the active LSI die through the upper RDL structure.

18. The method of claim 14, wherein the attaching of the plurality of second semiconductor dies to the upper RDL structure comprises attaching an array of the plurality of second semiconductor dies to the upper RDL structure, comprising:
attaching a first right column of the plurality of second semiconductor dies and a first left column of the plurality of second semiconductor dies located over the active LSI die and coupled to the first semiconductor die by the active LSI die; and
attaching a second right column of the plurality of second semiconductor dies and a second left column of the plurality of second semiconductor dies respectively located adjacent the first right column of the plurality of second semiconductor dies and the first left column of the plurality of second semiconductor dies, wherein the second right column of the plurality of second semiconductor dies and the second left column of the plurality of second semiconductor dies are located over the active LSI die and coupled to the first semiconductor die by the active LSI die.

19. A semiconductor module, comprising:
an interposer comprising:
a lower redistribution layer (RDL) structure;
an interposer molded portion on the lower RDL structure, comprising:
a through interposer via (TIV); and
an active local silicon interconnect (LSI) die including an active device and comprising a memory controller; and
an upper RDL structure on the interposer molded portion;
a first semiconductor die on the interposer and coupled to the lower RDL structure through the upper RDL structure and the TIV; and
a plurality of second semiconductor dies adjacent the first semiconductor die on the interposer and coupled to the memory controller in the active LSI die.

20. The semiconductor module of claim 19, wherein the interposer further comprises a passive LSI die, and the first semiconductor die and the plurality of second semiconductor dies are coupled to the passive LSI die.
